(19) United States
(12) Patent Application Publication
(10) Pub. No.: US 2024/0274190 A1
(43) Pub. Date: Aug. 15, 2024

(54) MEMORY CIRCUIT AND METHOD OF OPERATING SAME

(71) Applicant: TAIWAN SEMICONDUCTOR MANUFACTURING COMPANY, LTD., Hsinchu (TW)

(72) Inventors: Ku-Feng LIN, Hsinchu (TW); Chia-En HUANG, Hsinchu (TW)

(21) Appl. No.: 18/337,267

(22) Filed: Jun. 19, 2023

Related U.S. Application Data
(60) Provisional application No. 63/484,666, filed on Feb. 13, 2023.

(51) Int. Cl. G11C 13/00

(52) U.S. Cl. CPC G11C 13/0069; G11C 13/0026; G11C 13/004

(57) ABSTRACT

A memory circuit includes a memory cell, a first bit line, a selection circuit, a first word line, and a first source line. The selection circuit includes a first transistor on a first level, and a second transistor on the first level or a second level. The first word line is coupled to the first or second transistor. The first source line is coupled to the first or second transistor. The first and second transistor are part of a complementary field-effect transistor. The first transistor is configured to perform a write operation of the memory cell in response to the memory cell being configured to store a first logical value. The second transistor is configured to perform a read operation of the memory cell, and the write operation of the memory cell in response to the memory cell being configured to store a second logical value.

### PRIORITY CLAIM

This application claims the benefit of U.S. Provisional Application No. 63/484,666, filed Feb. 13, 2023, which is herein incorporated by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIG. 2 is a circuit diagram of a memory circuit, in accordance with some embodiments.

FIGS. 3A-3C are corresponding circuit diagrams of corresponding memory circuits, in accordance with some embodiments.

FIGS. 4A-4C is a corresponding timing diagram of waveforms of a memory circuit, in accordance with some embodiments.

FIG. 4D is a table of the waveforms of timing diagrams, in accordance with some embodiments.

FIG. 5 is a block diagram of a memory circuit, in accordance with some embodiments.

FIG. 6 is a circuit diagram of a memory circuit, in accordance with some embodiments.

FIG. 7 is a circuit diagram of a memory circuit, in accordance with some embodiments.

FIGS. 8A-8C is a corresponding timing diagram of waveforms of a memory circuit, in accordance with some embodiments.

FIG. 8D is a table of the waveforms of timing diagrams, in accordance with some embodiments.

FIG. 9 is a block diagram of a memory circuit, in accordance with some embodiments.

FIG. 10 is a circuit diagram of a memory circuit, in accordance with some embodiments.

FIG. 11 is a circuit diagram of a memory circuit, in accordance with some embodiments.

FIGS. 12A-12C is a corresponding timing diagram of waveforms of a memory circuit, in accordance with some embodiments.

FIG. 12D is a table of the waveforms of timing diagrams, in accordance with some embodiments.

FIG. 13 is a perspective view of a diagram of an integrated circuit, in accordance with some embodiments.

FIG. 14 is a flowchart of a method of operating a circuit, in accordance with some embodiments.

FIGS. 15A-15C are a flowchart of methods of operating a circuit, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, examples and are not limiting. Other components, materials, values, steps, arrangements, or the like, are contemplated. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a memory circuit includes a memory cell coupled to a first bit line.

In some embodiments, the memory circuit further includes a selection circuit coupled to the memory cell. In some embodiments, the selection circuit includes a first transistor on a first level, and a second transistor on a second level. In some embodiments, the second level is different from the first level.

In some embodiments, the memory circuit further includes a first word line coupled to at least the first transistor or the second transistor.

In some embodiments, the memory circuit further includes a first source line coupled to at least the first transistor or the second transistor.

In some embodiments, the first transistor and the second transistor are part of a complementary field-effect transistor (CFET).

In some embodiments, the second transistor is configured to perform a read operation of the memory cell.

In some embodiments, the first transistor is configured to write a first logical value to the memory cell during a write operation of the memory cell.

In some embodiments, the second transistor is configured to write a second logical value to the memory cell during the write operation of the memory cell. In some embodiments, the second logical value is different from the first logical value.

In some embodiments, using different transistors (e.g., first transistor and second transistor) to perform write operations of different corresponding values, results in simplified peripheral circuitry compared to other approaches.

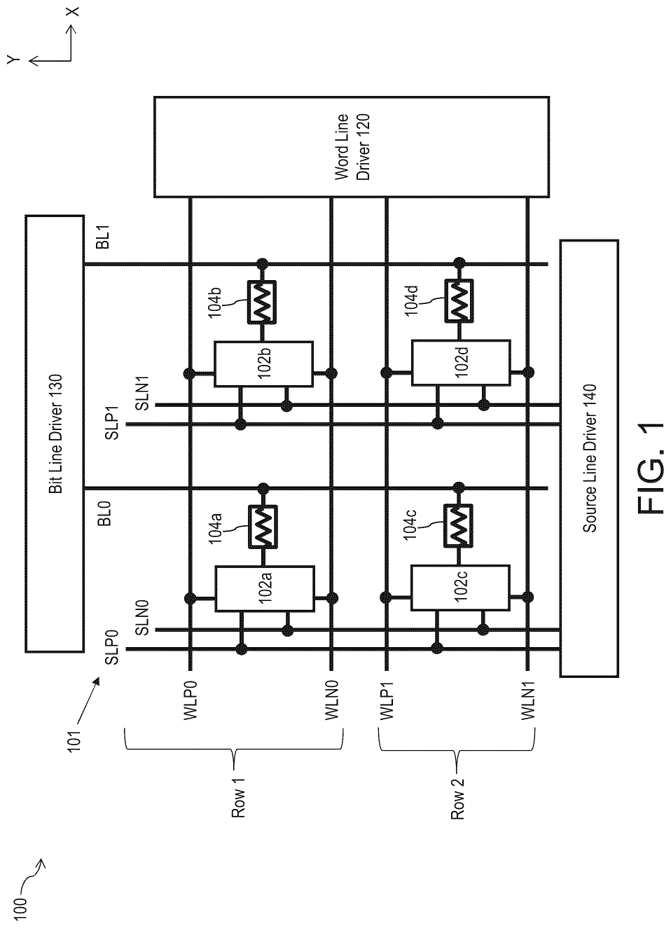

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged so as to perform the operations discussed below.

FIG. 1 is a circuit diagram of a memory circuit 100, in accordance with some embodiments. In the embodiment of FIG. 1, memory circuit 100 is a resistive random access memory (RRAM) circuit. RRAM is used for illustration, and other types of memories are within the scope of various embodiments. In the embodiment of FIG. 1, memory circuit 100 is a magnetic RAM (MRAM) circuit. In the embodiment of FIG. 1, memory circuit 100 is a phase change RAM (PCRAM) circuit. Other memory types are within the scope of the present disclosure.

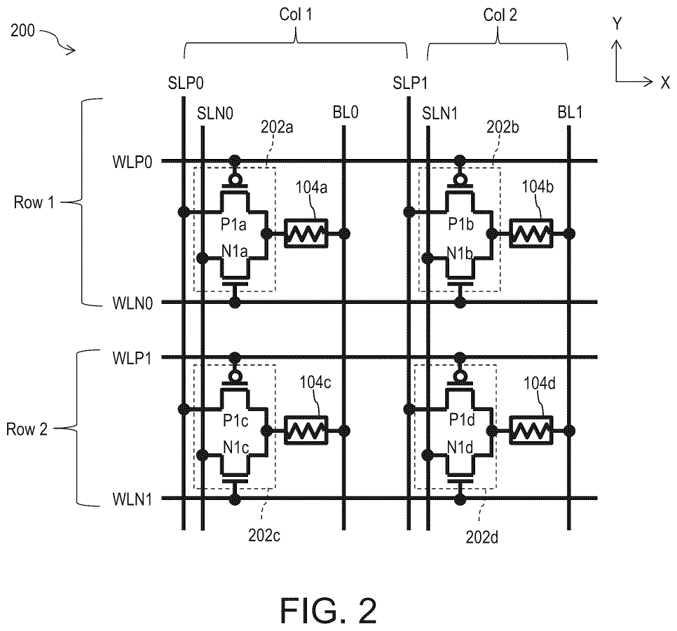

Memory circuit 100 comprises a memory cell array 104 having M rows and N columns of memory cells 104a, . . . , 104d. In some embodiments, N is a positive integer corresponding to the number of columns in memory cell array 104 and M is a positive integer corresponding to the number of rows in memory cell array 104. The rows of cells in memory cell array 104 are arranged in a first direction X. The columns of cells (labelled in FIG. 2) in memory cell array 104 are arranged in a second direction Y. The second direction Y is different from the first direction X. In some embodiments, the second direction Y is perpendicular to the first direction X.

For case of illustration, memory cell array 104 is shown as having 2 rows and 2 columns, but other numbers of rows or columns are within the scope of the present disclosure. The number of rows M in memory cell array 104 is equal to or greater than 1. The number of columns N in memory cell array 104 is equal to or greater than 1.

Memory cell 104a is a single memory cell in column 0 and row 0 of memory cell array 104. Memory cell 104b is a single memory cell in column 1 and row 0 of memory cell array 104. Memory cell 104c is a single memory cell in column 0 and row 1 of memory cell array 104. Memory cell 104d is a single memory cell in column 1 and row 1 of memory cell array 104.

In some embodiments, each memory cell 104a, 104b, 104c or 104d in memory cell array 104 is configured to store a bit of data. In some embodiments, each memory cell 104a, 104b, 104c or 104d in memory cell array 104 is an RRAM cell. In some embodiments, each memory cell 104a, 104b, 104c or 104d in memory cell array 104 is an MRAM cell. In some embodiments, each memory cell 104a, 104b, 104c or 104d in memory cell array 104 is a PCRAM cell. Different types of memory cells in memory cell array 104 are within the contemplated scope of the present disclosure.

Other configurations of the memory cell array 104 are within the scope of the present disclosure.

Memory circuit 100 further includes a selection circuit array 102 having M rows and N columns of selection circuits 102a, . . . , 102d. In some embodiments, N is a positive integer corresponding to the number of columns in selection circuit array 102, and M is a positive integer corresponding to the number of rows in selection circuit array 102. The rows of selection circuits in selection circuit array 102 are arranged in the first direction X. The columns of selection circuits (labelled in FIG. 2) in selection circuit array 102 are arranged in the second direction Y.

For case of illustration, selection circuit array 102 is shown as having 2 rows and 2 columns, but other numbers of rows or columns are within the scope of the present disclosure. The number of rows M in selection circuit array 102 is equal to or greater than 1. The number of columns N in selection circuit array 102 is equal to or greater than 1.

Selection circuit 102a is a single selection circuit in column 0 and row 0 of selection circuit array 102. Selection circuit 102b is a single selection circuit in column 1 and row 0 of selection circuit array 102. Selection circuit 102c is a single selection circuit in column 0 and row 1 of selection circuit array 102. Selection circuit 102d is a single selection circuit in column 1 and row 1 of selection circuit array 102.

In some embodiments, each selection circuit 102a, 102b, 102c or 102d in selection circuit array 102 is coupled to a corresponding memory cell 104a, 104b, 104c or 104d in memory cell array 104.

In some embodiments, each selection circuit 102a, 102b, 102c or 102d in selection circuit array 102 is configured to electrically couple corresponding memory cell 104a, 104b, 104c or 104d in memory cell array 104 to a source line SLP0, SLP1, SLN0 or SLN1 during a read or write operation of corresponding memory cell 104a, 104b, 104c or 104d in memory cell array 104.

In some embodiments, each selection circuit 102a, 102b, 102c or 102d in selection circuit array 102 includes a pair of transistors in a complementary field effect transistor (CFET). Different types of selection circuits in selection circuit array 102 are within the contemplated scope of the present disclosure.

Other configurations of the selection circuit array 102 are within the scope of the present disclosure.

Memory circuit 100 further includes N bit lines BL0, . . . BL1 (collectively referred to as “bit line BL”). Each column 1, . . . , N in memory cell array 104 is overlapped and coupled to a corresponding bit line BL0, . . . , BL1. Each bit line BL extends in the second direction Y and over a column of memory cells (e.g., column 1, . . . , N).

Memory circuit 100 further includes N source lines SLP0, . . . SLP1 (collectively referred to as “source line SLP”) and N source lines SLN0, . . . SLN1 (collectively referred to as “source line SLN”). Each column 1, . . . , N in selection circuit array 102 is overlapped and coupled to a corresponding source line SLP0, . . . SLP1 and a corresponding source line SLN0, . . . SLN1. Each source line SLP and source line SLN extends in the second direction Y and over a column of selection circuits (e.g., column 1, . . . , N).

Memory circuit 100 further includes M word lines WLP0, . . . WLP1 (collectively referred to as “word line WLP”) and M word lines WLN0, . . . WLN1 (collectively referred to as “word line WLN”). Each row 1, . . . , M in selection circuit array 102 is overlapped and coupled to a corresponding word line WLP0, . . . , WLP1 and a corresponding word line WLN0, . . . , WLN1. Each word line WLP or WLN extends in the first direction X and over a row of selection circuits (e.g., row 1, . . . , M).

In some embodiments, the selection circuit array 102, the memory cell array 104, the word lines WLP and WLN, bit line BL and source lines SLP and SLN are also referred to as an array circuit 101.

Other configurations of the word lines WLP and WLN, bit line BL or source lines SLP and SLN are within the scope of the present disclosure.

Memory circuit 100 further includes a word line driver 120.

The word line driver 120 is coupled to the selection circuit array 102 by the word line WLP and the word line WLN. In some embodiments, word line driver 120 is coupled to selection circuits 102a and 102b by word lines WLP0 and WLN0. In some embodiments, word line driver 120 is coupled to selection circuits 102c and 102d by word lines WLP1 and WLN1.

The word line driver 120 is configured to decode a row address of a memory cell in memory cell array 104 selected by a corresponding selection circuit in the selection circuit array 102 that is configured to be accessed in a read operation or a write operation. The word line driver 120 is configured to supply a set of voltages to the selected word lines WLP and WLN that corresponds to the decoded row address.

Memory circuit 100 further includes a bit line driver 130 and a source line driver 140.

The source line driver 140 and/or the bit line driver 130 is/are configured to decode a column address of a memory cell in memory cell array 104 selected by a corresponding selection circuit in the selection circuit array 102 that is configured to be accessed in a read operation or a write operation.

The bit line driver 130 is coupled to the memory cell array 104 by the bit line BL. In some embodiments, bit line driver 130 is coupled to memory cells 104a and 104c by bit line BL0. In some embodiments, bit line driver 130 is coupled to memory cells 104b and 104d by bit line BL1.

The source line driver 140 is coupled to the selection circuit array 102 by the source line SLP and the source line SLN. In some embodiments, source line driver 140 is coupled to selection circuits 102a and 102c by source lines SLP0 and SLN0. In some embodiments, source line driver 140 is coupled to selection circuits 102b and 102d by source lines SLP1 and SLN1.

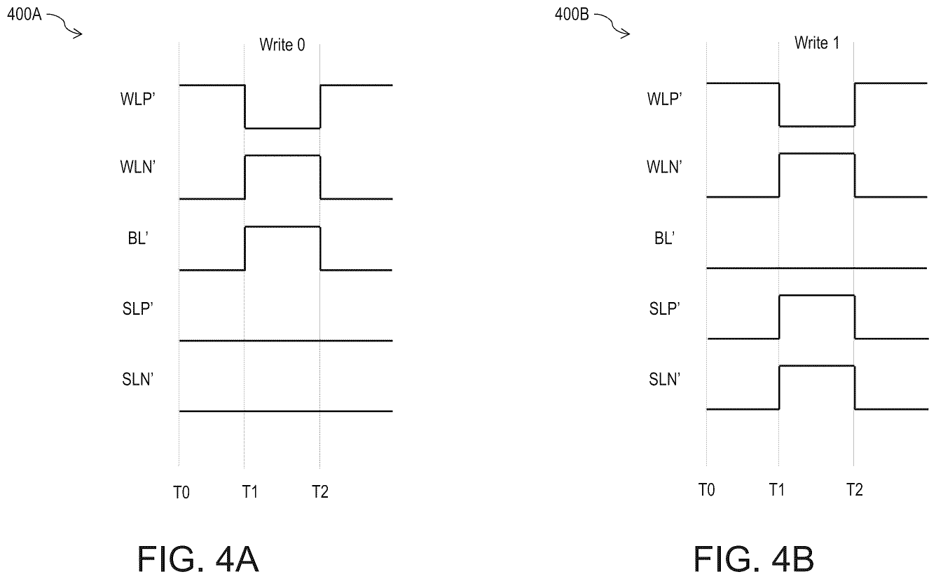

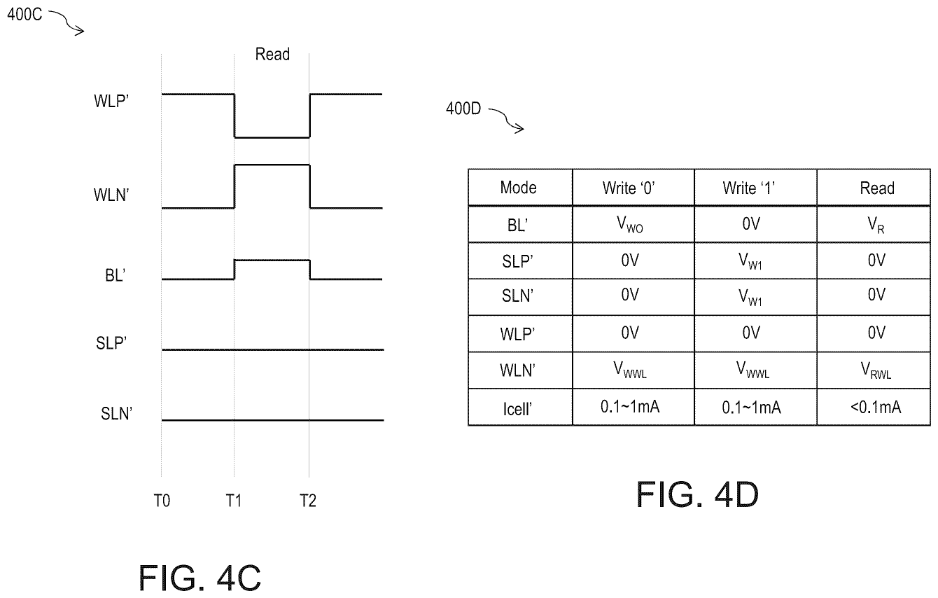

In some embodiments, the source line driver 140 and/or the bit line driver 130 is/are configured to supply a set of voltages (e.g., source line signals and bit line signals as shown in Table 400D of FIG. 4D) to the selected source lines SLP and SLN and the selected bit line BL corresponding to the selected memory cell 104a, 104b, 104c or 104d and/or the selected selection circuit 102a, 102b, 102c or 102d, and a different set of voltages (e.g., as shown in Table 400D of FIG. 4D) to the other, unselected source lines SLP and SLN and unselected bit lines BL. For example, in a write operation, the source line driver 140 is configured to supply a voltage (e.g., as shown in Table 400D of FIG. 4D) to the selected source line SLP or SLN, and the bit line driver 130 is configured to supply a voltage to the selected bit line BL, in accordance with some embodiments. For example, in a read operation, the source line driver 140 is configured to supply a voltage to the selected source line SLP or SLN, and the bit line driver 130 is configured to supply a voltage to the selected bit line BL, in accordance with some embodiments.

Other configurations of the word line driver 120, bit line driver 130 or source line driver 140 are within the scope of the present disclosure.

In some embodiments, memory circuit 100 also includes other circuits (e.g., timing circuits, etc.) that are not described for simplicity.

Other configurations of memory circuit 100 are within the scope of the present disclosure.

FIG. 2 is a circuit diagram of a memory circuit 200, in accordance with some embodiments.

Memory circuit 200 is an embodiment of the array circuit 101 of FIG. 1, and similar detailed description is therefore omitted. For example, memory circuit 200 illustrates a non-limiting example where each selection circuit 202a, 202b, 202c or 202d includes a corresponding P-type transistor (P1a, P1b, P1c or P1d) and a corresponding N-type transistor (N1a, N1b, N1c or N1d).

In some embodiments, selection circuit 202a, 202b, 202c or 202d of memory circuit 200 is useable as corresponding selection circuit 102a, 102b, 102c or 102d in selection circuit array 102 in FIG. 1, and similar detailed description is therefore omitted.

Memory circuit 200 includes a selection circuit array 202, the memory cell array 104, the word lines WLP and WLN, bit line BL and source lines SLP and SLN.

In comparison with memory circuit 100 of FIG. 1, selection circuit array 202 of FIG. 2 replaces selection circuit array 102, and similar detailed description is therefore omitted.

Selection circuit array 202 includes selection circuits 202a, 202b, 202c and 202d. Selection circuit 202a, 202b, 202c and 202d is an embodiment of corresponding selection circuit 102a, 102b, 102c and 102d, and similar detailed description is therefore omitted.

Selection circuit 202a includes a transistor P1a and a transistor N1a.

Selection circuit 202b includes a transistor P1b and a transistor N1b.

Selection circuit 202c includes a transistor P1c and a transistor N1c.

Selection circuit 202d includes a transistor P1d and a transistor N1d.

Transistor P1a is a P-type transistor, and transistor N1a is an N-type transistor. In some embodiments, transistor P1a is an N-type transistor, and transistor N1a is a P-type transistor.

Transistor P1b is a P-type transistor, and transistor N1b is an N-type transistor. In some embodiments, transistor P1b is an N-type transistor, and transistor N1b is a P-type transistor.

Transistor P1c is a P-type transistor, and transistor N1c is an N-type transistor. In some embodiments, transistor P1c is an N-type transistor, and transistor N1c is a P-type transistor.

Transistor P1d is a P-type transistor, and transistor N1d is an N-type transistor. In some embodiments, transistor P1d is an N-type transistor, and transistor N1d is a P-type transistor.

Each of a gate terminal of transistor P1a, a gate terminal of transistor P1b, and the word line WLP0 are coupled together. Each of a gate terminal of transistor N1a, a gate terminal of transistor N1b, and the word line WLN0 are coupled together.

Each of a drain terminal of transistor P1a, a drain terminal of transistor N1a and a first end of memory cell 104a are coupled together. The bit line BL0 is coupled with a second end of memory cell 104a.

Each of a source terminal of transistor P1a, a source terminal of transistor P1c, and the source line SLP0 are coupled together. Each of a source terminal of transistor N1a, a source terminal of transistor N1c, and the source line SLN0 are coupled together.

Each of a drain terminal of transistor P1b, a drain terminal of transistor N1b and a first end of memory cell 104b are coupled together. The bit line BL1 is coupled with a second end of memory cell 104b.

Each of a source terminal of transistor P1b, a source terminal of transistor P1d, and the source line SLP1 are coupled together. Each of a source terminal of transistor N1b, a source terminal of transistor N1d, and the source line SLN1 are coupled together.

Each of a gate terminal of transistor P1c, a gate terminal of transistor P1d, and the word line WLP1 are coupled together. Each of a gate terminal of transistor N1c, a gate terminal of transistor N1d, and the word line WLN1 are coupled together.

Each of a drain terminal of transistor P1c, a drain terminal of transistor N1c and a first end of memory cell 104c are coupled together. The bit line BL0 is coupled with a second end of memory cell 104c.

Each of a drain terminal of transistor P1d, a drain terminal of transistor N1d and a first end of memory cell 104d are coupled together. The bit line BL1 is coupled with a second end of memory cell 104d.

In some embodiments, transistor P1a and transistor N1a are part of a first complementary field-effect transistor (CFET). In some embodiments, transistor P1b and transistor N1b are part of a second CFET. In some embodiments, transistor P1c and transistor N1c are part of a third CFET. In some embodiments, transistor P1d and transistor N1d are part of a fourth CFET.

In some embodiments, at least transistor P1a, P1b, P1c or P1d is configured to write a first logical value to a corresponding memory cell 104a, 104b, 104c or 104d, and at least transistor N1a, N1b, N1c or N1d is configured to write a second logical value to corresponding memory cell 104a, 104b, 104c or 104d. The second logical value is different from the first logical value. In some embodiments, the first logical value is a logic 1, and the second logical value is a logic 0. In some embodiments, the first logical value is a logic 0, and the second logical value is a logic 1.

In some embodiments, at least transistor P1a, P1b, P1c or P1d is configured to perform a write operation of corresponding memory cell 104a, 104b, 104c or 104d in response to corresponding memory cell 104a, 104b, 104c or 104d being configured to store the first logical value. In some embodiments, at least transistor N1a, N1b, N1c or N1d is configured to perform a write operation of corresponding memory cell 104a, 104b, 104c or 104d in response to corresponding memory cell 104a, 104b, 104c or 104d being configured to store the second logical value.

In some embodiments, at least transistor N1a, N1b, N1c or N1d is configured to perform a read operation of corresponding memory cell 104a, 104b, 104c or 104d.

Other configurations or numbers of at least transistor P1a, P1b, P1c or P1d are within the scope of the present disclosure.

Other configurations or numbers of at least transistor N1a, N1b, N1c or N1d are within the scope of the present disclosure.

In some embodiments, at least transistor P1a, P1b, P1c or P1d is configured to write a first logical value to a corresponding memory cell 104a, 104b, 104c or 104d, and at least transistor N1a, N1b, N1c or N1d is configured to write a second logical value to corresponding memory cell 104a, 104b, 104c or 104d.

In some embodiments, using different transistors (e.g., first transistor and second transistor) to perform write operations of different corresponding values, results in simplified peripheral circuitry compared to other approaches.

In some embodiments, using different transistors (e.g., transistor N1a, N1b, N1c or N1d and transistor P1a, P1b, P1c or P1d) to perform write operations of different corresponding values (e.g., logic 0 and logic 1), results in lower word line voltages for at least transistor N1a, N1b, N1c or N1d thereby causing no source degeneration of at least transistor N1a, N1b, N1c or N1d. In some embodiments, by causing no source degeneration of at least transistor N1a, N1b, N1c or N1d, results in improved reliability of memory circuit 200 compared to other approaches. In some embodiments, by causing no source degeneration of at least transistor N1a, N1b, N1c or N1d, results in simpler peripheral circuitry compared to other approaches, and further resulting in improved power performance and area (PPA) of memory circuit 200 compared to other approaches.

Other configurations of memory circuit 200 are within the scope of the present disclosure.

### Selection Circuit and Memory Cell

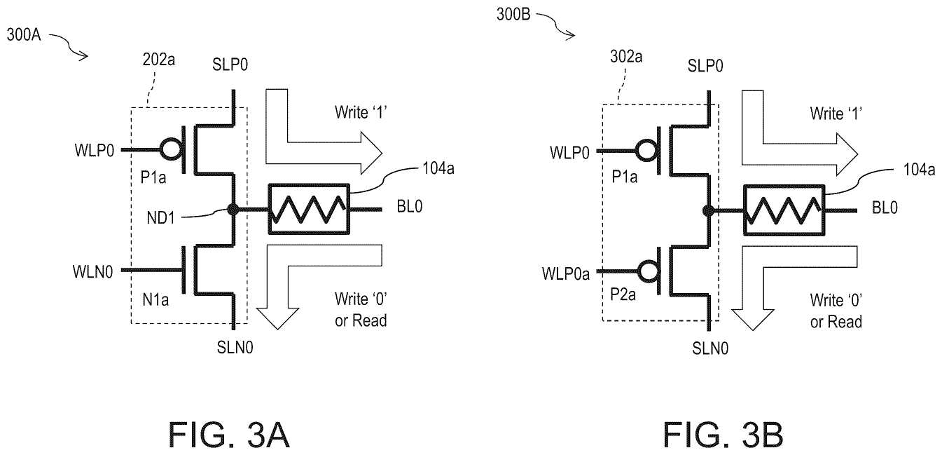

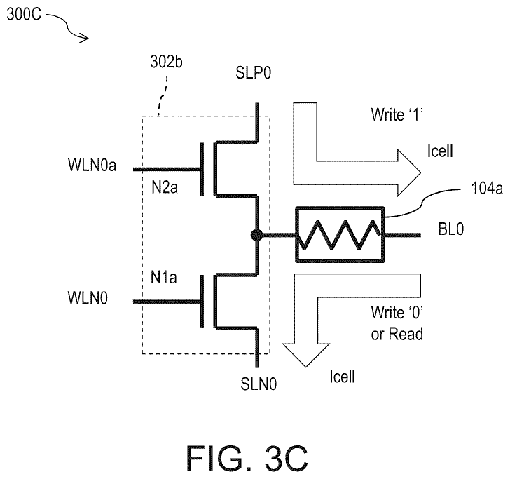

FIGS. 3A-3C are corresponding circuit diagrams of corresponding memory circuits 300A-300C, in accordance with some embodiments.

Memory circuit 300A is one column (COL 1) and one row (Row 1) of memory circuit 200 of FIG. 2, and similar detailed description is therefore omitted. For example, memory circuit 300A illustrates a non-limiting example of one column (COL 1) and one row (Row 1) of the selection circuit 202a of selection circuit array 202 and one column (COL 1) and one row (Row 1) of the memory cell 104a of memory cell array 104 of FIGS. 1-2, and similar detailed description is therefore omitted.

In some embodiments, memory circuit 300A corresponds to at least one of other rows or other columns in memory circuit 200, and similar detailed description is therefore omitted.

Memory circuit 300A includes selection circuit 202a, memory cell 104a and source lines SLP0 and SLN0, word lines WLP0 and WLN0, and bit line BL0.

Selection circuit 202a includes transistor P1a and transistor N1a.

As shown in FIG. 3A, transistor P1a is configured to write the first logical value (e.g., logic 1) to memory cell 104a, in accordance with some embodiments. Details of write operations and read operations of memory cell 104a by selection circuit 202a are described below in FIGS. 4A-4D.

As shown in FIG. 3A, transistor N1a is configured to write the second logical value (e.g., logic 0) to memory cell 104a.

As shown in FIG. 3A, transistor N1a is configured to perform a read operation of memory cell 104a.

Other configurations of memory circuit 300A are within the scope of the present disclosure.

FIG. 3B is a circuit diagram of a memory circuit 300B, in accordance with some embodiments.

Memory circuit 300B is a variation of memory circuit 300A of FIG. 3A, and similar detailed description is therefore omitted. For example, memory circuit 300B illustrates a non-limiting example where two P-type transistors are used as a selection circuit 302a, and similar detailed description is therefore omitted.

In some embodiments, memory circuit 300B is usable as at least one or more rows or columns in memory circuit 200, and similar detailed description is therefore omitted. In some embodiments, selection circuit 302a of memory circuit 300B is useable as one or more selection circuits 202a, 202b, 202c or 202d in selection circuit array 202 in FIG. 2, and similar detailed description is therefore omitted.

Memory circuit 300B includes selection circuit 302a, memory cell 104a and source lines SLP0 and SLN0, word lines WLP0 and WLP0a, and bit line BL0.

Selection circuit 302a includes transistor P1a and a transistor P2a.

In comparison with FIG. 3A, selection circuit 302a replaces selection circuit 202a, transistor P2a replaces transistor N1a, and word line WLP0a replaces word line WLN0, and similar detailed description is therefore omitted.

A gate terminal of transistor P2a is coupled to the word line WLP0a.

Each of the drain terminal of transistor P1a, a drain terminal of transistor P2a and the first end of memory cell 104a are coupled together.

A source terminal of transistor P2a is coupled to the source line SLN0.

As shown in FIG. 3B, transistor P1a is configured to write the first logical value (e.g., logic 1) to memory cell 104a, in accordance with some embodiments. Details of write operations and read operations of memory cell 104a by selection circuit 302a are described below in FIGS. 4A-4D.

As shown in FIG. 3B, transistor P2a is configured to write the second logical value (e.g., logic 0) to memory cell 104a.

As shown in FIG. 3B, transistor P2a is configured to perform a read operation of memory cell 104a.

Other configurations of memory circuit 300B are within the scope of the present disclosure.

FIG. 3C is a circuit diagram of a memory circuit 300C, in accordance with some embodiments.

Memory circuit 300C is a variation of memory circuit 300A of FIG. 3A, and similar detailed description is therefore omitted. For example, memory circuit 300C illustrates a non-limiting example where two N-type transistors are used as a selection circuit 302b, and similar detailed description is therefore omitted.

In some embodiments, memory circuit 300C is usable as at least one or more rows or columns in memory circuit 200, and similar detailed description is therefore omitted. In some embodiments, selection circuit 302b of memory circuit 300C is useable as one or more selection circuits 202a, 202b, 202c or 202d in selection circuit array 202 in FIG. 2, and similar detailed description is therefore omitted.

Memory circuit 300C includes selection circuit 302b, memory cell 104a, source lines SLP0 and SLN0, word lines WLN0 and WLN0a, and bit line BL0.

Selection circuit 302b includes transistor N1a and a transistor N2a.

In comparison with FIG. 3A, selection circuit 302b replaces selection circuit 202a, transistor N2a replaces transistor P1a, and word line WLN0a replaces word line WLP0, and similar detailed description is therefore omitted.

A gate terminal of transistor N2a is coupled to the word line WLN0a.

Each of the drain terminal of transistor N1a, a drain terminal of transistor N2a and the first end of memory cell 104a are coupled together.

A source terminal of transistor N2a is coupled to the source line SLP0.

As shown in FIG. 3C, transistor N2a is configured to write the first logical value (e.g., logic 1) to memory cell 104a, in accordance with some embodiments.

As shown in FIG. 3C, transistor N1a is configured to write the second logical value (e.g., logic 0) to memory cell 104a.

As shown in FIG. 3C, transistor N1a is configured to perform a read operation of memory cell 104a. Details of write operations and read operations of memory cell 104a by selection circuit 302b are described below in FIGS. 4A-4D.

Other configurations of memory circuit 300C are within the scope of the present disclosure.

In some embodiments, at least one of memory circuit 300A, 300B or 300C operates to achieve one or more benefits described herein including the details discussed herein.

### Waveforms

FIGS. 4A-4C is a corresponding timing diagram 400A-400C of waveforms of a memory circuit 300A, in accordance with some embodiments.

In some embodiments, FIGS. 4A-4C is a corresponding timing diagram 400A-400C of waveforms of memory circuit 100 in FIG. 1, memory circuit 200 in FIG. 2, memory circuit 300B in FIG. 3B, or memory circuit 300C in FIG. 3C, in accordance with some embodiments.

In some embodiments, timing diagram 400A includes waveforms of signals when transistor N1a is configured to write the second logical value (e.g., logic 0) to memory cell 104a.

In some embodiments, timing diagram 400B includes waveforms of signals when transistor P1a is configured to write the first logical value (e.g., logic 1) to memory cell 104a.

In some embodiments, timing diagram 400C includes waveforms of signals when transistor N1a is configured to perform a read operation of memory cell 104a.

In some embodiments, the one or more read operations and write operations of FIGS. 4A-4D are applicable to at least one column (COL 1) and one row (Row 1) of selection circuit of selection circuit array 202 and at least one memory cell of memory cell array 104 of FIGS. 1-2, and similar detailed description is therefore omitted.

Timing diagram 400A, 400B and 400C each include waveforms of a word line signal WLP′ of word line WLP0, a word line signal WLN′ of a word line WLN0, a source line signal SLP′ of a source line SLP0, a source line signal SLN′ of a source line SLN0, and a bit line signal BL′ of a bit line BL.

At time TO in FIG. 4A, the word line signal WLP′ is logically high (e.g., voltage V_{WWL}), and each of the word line signal WLN′, the source line signal SLP′, the source line signal SLN′ and the bit line signal BL′ is logically low.

At time T1 in FIG. 4A, the word line signal WLN′ transitions from logically low to a voltage V_{WWL} thereby causing transistor N1a to turn on, and the bit line signal BL′ transitions from logically low to a voltage V_{W0}.

For example, at time T1, in response to the word line signal WLN′ transitioning from logically low to the voltage V_{WWL}, and the source line signal SLN′ being logically low, the gate to source voltage VGS of transistor N1a is greater than a threshold voltage Vth of transistor N1a thereby causing transistor N1a to turn on, and thus coupling the source line SLN to the first end ND1 of memory cell 104a. In some embodiments, in response to the source line SLN being coupled to the first end ND1 of memory cell 104a by transistor N1a, and the bit line voltage being set at voltage V_{W0}, transistor N1a is configured to write the second logical value (e.g., logic 0) to memory cell 104a.

In some embodiments, the voltage V_{WWL} is greater than 1.4 multiplied by a supply voltage VDD (e.g., 1.4*VDD).

In some embodiments, the voltage V_{W0} is less than 1.2 multiplied by the supply voltage VDD (e.g., 1.2*VDD).

At time T1 in FIG. 4A, the word line signal WLP′ transitions from voltage V_{WWL} to logically low thereby causing transistor P1a to turn off. For example, at time T1, in response to the word line signal WLP′ transitioning from voltage V_{WWL} to logically low, and the source line signal SLP′ being logically low, the gate to source voltage VGS of transistor P1a is greater than a negative threshold voltage −Vth of transistor P1a thereby causing transistor P1a to turn off, and thus decoupling the source line SLP from the first end ND1 of memory cell 104a.

At time T2 in FIG. 4A, the word line signal WLN′ transitions from voltage V_{WWL} to logically low thereby causing transistor N1a to turn off, and the bit line signal BL′ transitions from voltage V_{W0} to logically low.

At time T2 in FIG. 4A, the word line signal WLP′ transitions from logically low to voltage V_{WWL}.

In some embodiments, by utilizing timing diagram 400A, at least one of memory circuit 300A, 300B or 300C operates to achieve one or more benefits described herein including the details discussed herein.

Other configurations of timing diagram 400A are within the scope of the present disclosure.

FIG. 4B is a timing diagram 400B of waveforms of a memory circuit 300A, in accordance with some embodiments.

In some embodiments, FIG. 4B is a timing diagram 400B of waveforms of memory circuit 100 in FIG. 1, memory circuit 200 in FIG. 2, memory circuit 300A in FIG. 3A, memory circuit 300B in FIG. 3B, or memory circuit 300C in FIG. 3C, in accordance with some embodiments.

In some embodiments, timing diagram 400B includes waveforms of signals when transistor P1a is configured to write the first logical value (e.g., logic 1) to memory cell 104b.

At time T0 in FIG. 4B, the word line signal WLP′ is logically high (e.g., voltage V_{WWL}), and each of the word line signal WLN′, the source line signal SLP′, the source line signal SLN′ and the bit line signal BL′ is logically low.

At time T1 in FIG. 4B, the word line signal WLN′ transitions from logically low to a voltage V_{WWL} and the source line signal SLN′ transitions from logically low to a voltage V_{W1}, thereby causing transistor N1a to turn off. For example, at time T1, in response to the word line signal WLN′ transitioning from logically low to the voltage V_{WWL}, and the source line signal SLN′ transitioning from logically low to the voltage V_{W1}, the gate to source voltage VGS of transistor N1a is less than the threshold voltage Vth of transistor N1a thereby causing transistor N1a to turn off, and thus decoupling the source line SLN from the first end ND1 of memory cell 104b.

In some embodiments, the voltage V_{W1} is less than 1.2 multiplied by the supply voltage VDD (e.g., 1.2*VDD).

At time T1 in FIG. 4B, the word line signal WLP′ transitions from voltage V_{WWL} to logically low, and the source line signal SLP′ transitions from logically low to the voltage V_{W1}, thereby causing transistor P1a to turn on. For example, at time T1, in response to the word line signal WLP′ transitioning from voltage V_{WWL} to logically low, and the source line signal SLP′ transitioning to voltage V_{W1}, the gate to source voltage VGS of transistor P1a is less than the negative threshold voltage −Vth of transistor P1a, thus turning on transistor P1a and coupling the source line SLP to the first end ND1 of memory cell 104b. In some embodiments, in response to the source line SLP being coupled to the first end ND1 of memory cell 104b by transistor P1a, and the bit line voltage being set at logically low, transistor P1a is configured to write the first logical value (e.g., logic 1) to memory cell 104b.

At time T2 in FIG. 4B, the word line signal WLP′ transitions from logically low to voltage V_{WWL}, and the source line signal SLP′ transitions from voltage V_{W1} to logically low.

At time T2 in FIG. 4B, the word line signal WLN′ transitions from voltage V_{WWL} to logically low, and the source line signal SLP′ transitions from voltage V_{W1} to logically low thereby causing transistor N1a to turn off.

In some embodiments, by utilizing timing diagram 400B, at least one of memory circuit 300A, 300B or 300C operates to achieve one or more benefits described herein including the details discussed herein.

Other configurations of timing diagram 400B are within the scope of the present disclosure.

FIG. 4C is a timing diagram 400C of waveforms of a memory circuit 300A, in accordance with some embodiments.

In some embodiments, FIG. 4C is a timing diagram 400C of waveforms of memory circuit 100 in FIG. 1, memory circuit 200 in FIG. 2, memory circuit 300A in FIG. 3A, memory circuit 300B in FIG. 3B, or memory circuit 300C in FIG. 3C, in accordance with some embodiments.

In some embodiments, timing diagram 400C includes waveforms of signals when transistor N1a is configured to perform a read operation of memory cell 104c.

At time T0 in FIG. 4C, the word line signal WLP′ is logically high (e.g., voltage V_{RWL}), and each of the word line signal WLN′, the source line signal SLP′, the source line signal SLN′ and the bit line signal BL′ is logically low.

At time T1 in FIG. 4C, the word line signal WLN′ transitions from logically low to a voltage V_{RWL} thereby causing transistor N1a to turn on, and the bit line signal BL′ transitions from logically low to a voltage V_{R}. For example, at time T1, in response to the word line signal WLN′ transitioning from logically low to the voltage V_{RWL}, and the source line signal SLN′ being logically low, the gate to source voltage VGS of transistor N1a is greater than a threshold voltage Vth of transistor N1a thereby causing transistor N1a to turn on, and thus coupling the source line SLN to the first end ND1 of memory cell 104c. In some embodiments, in response to the source line SLN being coupled to the first end ND1 of memory cell 104c by transistor N1a, and the bit line voltage being set at voltage V_{R}, transistor N1a is configured to read the data stored in memory cell 104c.

In some embodiments, the voltage V_{RWL} is greater than 1.2 multiplied by a supply voltage VDD (e.g., 1.2*VDD).

In some embodiments, the voltage V_{R} is less than the supply voltage VDD.

At time T1 in FIG. 4C, the word line signal WLP′ transitions from voltage V_{RWL} to logically low thereby causing transistor P1a to turn off. For example, at time T1, in response to the word line signal WLP′ transitioning from voltage V_{RWL} to logically low, and the source line signal SLP′ being logically low, the gate to source voltage VGS of transistor P1a is greater than a negative threshold voltage −Vth of transistor P1a thereby causing transistor P1a to turn off, and thus decoupling the source line SLP from the first end ND1 of memory cell 104c.

At time T2 in FIG. 4C, the word line signal WLN′ transitions from voltage V_{RWL} to logically low thereby causing transistor N1a to turn off, and the bit line signal BL′ transitions from voltage V_{R} to logically low.

At time T2 in FIG. 4C, the word line signal WLP′ transitions from logically low to voltage V_{RWL}.

In some embodiments, by utilizing timing diagram 400C, at least one of memory circuit 300A, 300B or 300C operates to achieve one or more benefits described herein including the details discussed herein.

Other configurations of timing diagram 400C are within the scope of the present disclosure.

### Table

FIG. 4D is a table 400D of the waveforms of timing diagrams 400A-400C, in accordance with some embodiments.

Table 400D includes values of word line signal WLP′ of word line WLP0, values of word line signal WLN′ of word line WLN0, values of source line signal SLP′ of source line SLP0, values of source line signal SLN′ of source line SLN0, and values of bit line signal BL′ of bit line BL from FIGS. 4A-4C in a tabular form simplified for ease of discussion.

Table 400D further includes values of a cell current Icell for the write operations of timing diagrams 400A-400B, and the read operation of timing diagram 400C, in accordance with some embodiments. In some embodiments, the cell current Icell is the current of the memory cell 104a.

Other configurations of table 400D are within the scope of the present disclosure.

### Memory Circuit

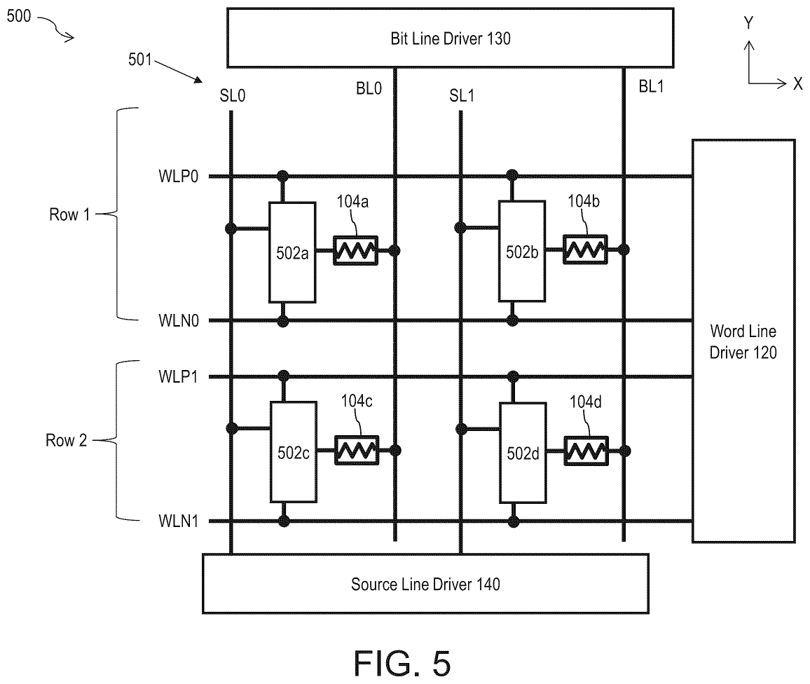

FIG. 5 is a block diagram of a memory circuit 500, in accordance with some embodiments.

Memory circuit 500 is a variation of memory circuit 100 of FIG. 1, and similar detailed description is therefore omitted. For example, memory circuit 500 illustrates a non-limiting example where each selection circuit in selection circuit array 502 is coupled to a single source line (e.g., SL0 or SL1), and similar detailed description is therefore omitted.

Memory circuit 500 includes a selection circuit array 502, memory cell array 104, source lines SL0 and SL1, word lines WLP0 and WLP1, word lines WLN0 and WLN1, bit lines BL0 and BL1, word line driver 120, bit line driver 130, and source line driver 140.

In comparison with FIG. 1, selection circuit array 502 replaces selection circuit array 102, source line SL0 replaces source lines SLP0 and SLN0, and source line SL1 replaces source lines SLP1 and SLN1, and similar detailed description is therefore omitted.

Selection circuit array 502 includes selection circuits 502a, 502b, 502c and 502d.

In comparison with FIG. 1, selection circuits 502a, 502b, 502c and 502d replace corresponding selection circuits 102a, 102b, 102c and 102d, and similar detailed description is therefore omitted.

For case of illustration, selection circuit array 502 is shown as having 2 rows and 2 columns, but other numbers of rows or columns are within the scope of the present disclosure.

The number of rows in selection circuit array 502 is equal to or greater than 1. The number of columns in selection circuit array 502 is equal to or greater than 1.

In some embodiments, each selection circuit 502a, 502b, 502c or 502d in selection circuit array 502 includes a pair of transistors in a CFET. Different types of selection circuits in selection circuit array 502 are within the contemplated scope of the present disclosure.

Other configurations of the selection circuit array 502 are within the scope of the present disclosure.

Memory circuit 500 includes N source lines SL0, . . . SL1 (collectively referred to as “source line SL”). Each column 1, . . . , N in selection circuit array 502 is overlapped and coupled to a corresponding source line SL0, . . . SL1. Each source line SL extends in the second direction Y and over a column of selection circuits (e.g., column 1, . . . , N).

In some embodiments, the selection circuit array 502, the memory cell array 104, the word lines WLP and WLN, bit line BL and source lines SL are also referred to as an array circuit 501.

Other configurations of the word lines WLP and WLN, bit line BL or source line SL are within the scope of the present disclosure.

In some embodiments, memory circuit 500 also includes other circuits (e.g., timing circuits, etc.) that are not described for simplicity.

In some embodiments, memory circuit 500 operates to achieve one or more benefits described herein including the details discussed herein.

Other configurations of memory circuit 500 are within the scope of the present disclosure.

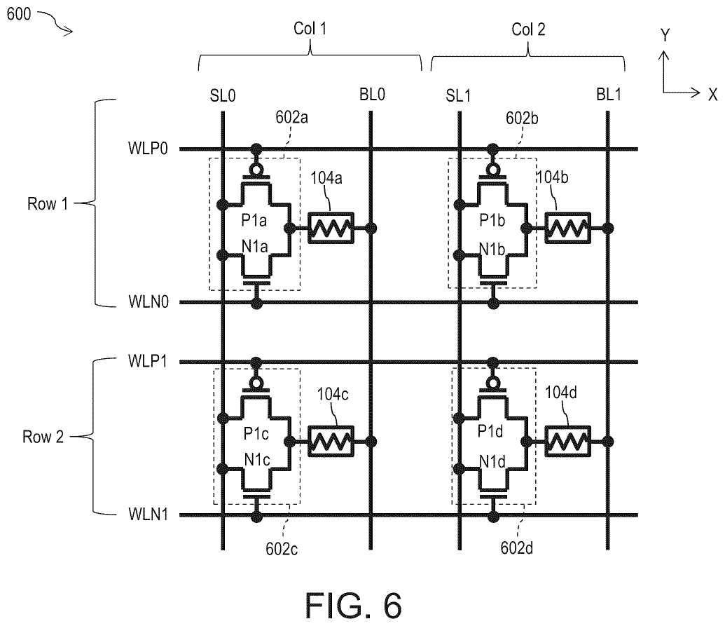

FIG. 6 is a block diagram of a memory circuit 600, in accordance with some embodiments.

Memory circuit 600 is a variation of memory circuit 200 of FIG. 2, and similar detailed description is therefore omitted. For example, memory circuit 600 illustrates a non-limiting example where each selection circuit in selection circuit array 602 is coupled to a single source line (e.g., SL0 and SL1), and similar detailed description is therefore omitted.

Memory circuit 600 is an embodiment of the array circuit 501 of FIG. 5, and similar detailed description is therefore omitted. For example, memory circuit 600 illustrates a non-limiting example where each selection circuit 602a, 602b, 602c or 602d includes a corresponding P-type transistor (P1a, P1b, P1c or P1d) and a corresponding N-type transistor (N1a, N1b, N1c or N1d).

In some embodiments, selection circuit 602a, 602b, 602c or 602d of memory circuit 600 is useable as corresponding selection circuit 502a, 502b, 502c or 502d in selection circuit array 502 in FIG. 5, and similar detailed description is therefore omitted.

Memory circuit 600 includes a selection circuit array 602, memory cell array 104, source lines SL0 and SL1, word lines WLP0 and WLP1, word lines WLN0 and WLN1, and bit lines BL0 and BL1.

Selection circuit array 602 includes selection circuits 602a, 602b, 602c and 602d.

Selection circuit array 602 is a variation of selection circuit array 202 of FIG. 2, and similar detailed description is therefore omitted. In comparison with FIG. 2, selection circuits 602a, 602b, 602c and 602d of selection circuit array 602 replace corresponding selection circuits 202a, 202b, 202c and 202d of selection circuit array 202, and similar detailed description is therefore omitted.

Selection circuit 602a includes transistor P1a and transistor N1a.

Selection circuit 602b includes transistor P1b and transistor N1b.

Selection circuit 602c includes transistor P1c and transistor N1c.

Selection circuit 602d includes transistor P1d and transistor N1d.

In FIG. 6, each of the source terminal of transistor P1a, the source terminal of transistor P1c, the source terminal of transistor N1a, the source terminal of transistor N1c and the source line SL0 are coupled together.

In some embodiments, coupling the source terminal of transistor P1a and the source terminal of transistor N1a together causes transistors P1a and N1a to be configured as a transmission gate. In some embodiments, coupling the source terminal of transistor P1b and the source terminal of transistor N1b together causes transistors P1b and N1b to be configured as a transmission gate.

In FIG. 6, each of the source terminal of transistor P1b, the source terminal of transistor P1d, the source terminal of transistor N1b, the source terminal of transistor N1d and the source line SL1 are coupled together.

In some embodiments, coupling the source terminal of transistor P1c and the source terminal of transistor N1c together causes transistors P1c and N1c to be configured as a transmission gate. In some embodiments, coupling the source terminal of transistor P1d and the source terminal of transistor N1d together causes transistors P1d and N1d to be configured as a transmission gate.

Other configurations of the selection circuit array 602 are within the scope of the present disclosure.

Other configurations of the word lines WLP and WLN, bit line BL or source line SL are within the scope of the present disclosure.

In some embodiments, memory circuit 600 also includes other circuits (e.g., timing circuits, etc.) that are not described for simplicity.

In some embodiments, memory circuit 600 operates to achieve one or more benefits described herein including the details discussed herein.

Other configurations of memory circuit 600 are within the scope of the present disclosure.

### Selection Circuit and Memory Cell

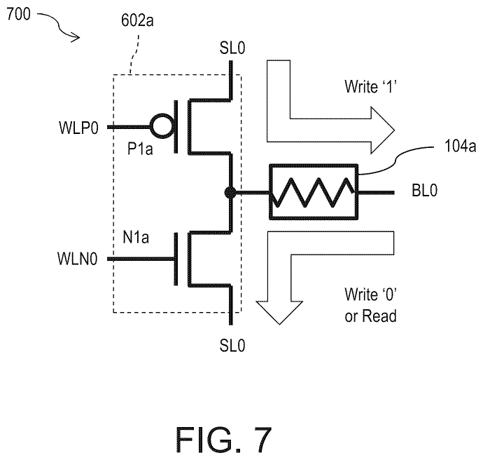

FIG. 7 is a circuit diagram of a memory circuit 700, in accordance with some embodiments.

Memory circuit 700 is one column (COL 1) and one row (Row 1) of memory circuit 600 of FIG. 6, and similar detailed description is therefore omitted. For example, memory circuit 700 illustrates a non-limiting example of one column (COL 1) and one row (Row 1) of the selection circuit 602a of selection circuit array 602 and one column (COL 1) and one row (Row 1) of the memory cell 104a of memory cell array 104 of FIGS. 5-6, and similar detailed description is therefore omitted.

In some embodiments, memory circuit 700 corresponds to at least one of other rows or other columns in memory circuit 600, and similar detailed description is therefore omitted.

Memory circuit 700 includes selection circuit 602a, memory cell 104a and source line SL0, word lines WLP0 and WLN0, and bit line BL0.

Selection circuit 602a includes transistor P1a and transistor N1a.

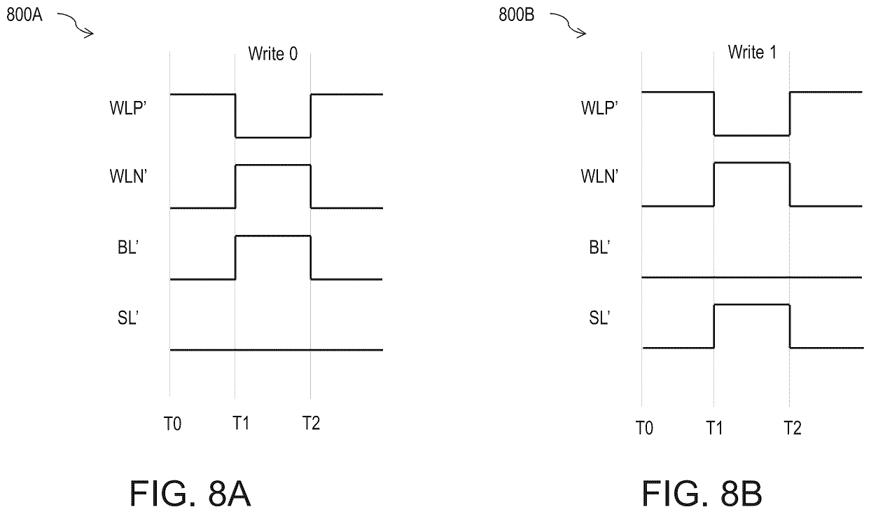

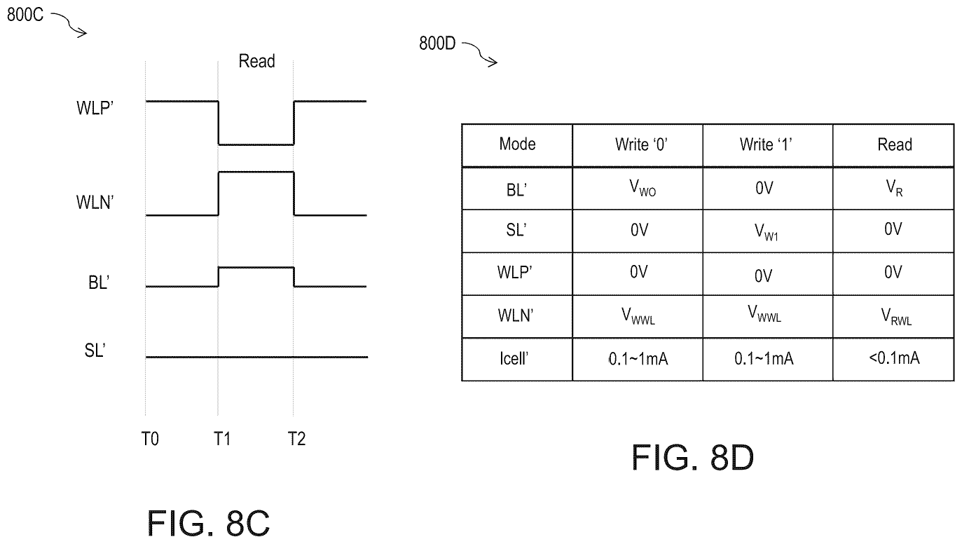

As shown in FIG. 7, transistor P1a is configured to write the first logical value (e.g., logic 1) to memory cell 104a, in accordance with some embodiments. Details of write operations and read operations of memory cell 104a by selection circuit 602a are described below in FIGS. 8A-8D.

As shown in FIG. 7, transistor N1a is configured to write the second logical value (e.g., logic 0) to memory cell 104a.

As shown in FIG. 7, transistor N1a is configured to perform a read operation of memory cell 104a.

In some embodiments, memory circuit 700 operates to achieve one or more benefits described herein including the details discussed herein.

Other configurations of memory circuit 700 are within the scope of the present disclosure.

### Waveforms

FIGS. 8A-8C is a corresponding timing diagram 800A-800C of waveforms of a memory circuit 700, in accordance with some embodiments.

In some embodiments, FIGS. 8A-8C is a corresponding timing diagram 800A-800C of waveforms of memory circuit 500 in FIG. 5 or memory circuit 600 in FIG. 6, in accordance with some embodiments.

In some embodiments, timing diagram 800A includes waveforms of signals when transistor N1a of FIG. 7 is configured to write the second logical value (e.g., logic 0) to memory cell 104a.

In some embodiments, timing diagram 800B includes waveforms of signals when transistor P1a of FIG. 7 is configured to write the first logical value (e.g., logic 1) to memory cell 104a.

In some embodiments, timing diagram 800C includes waveforms of signals when transistor N1a of FIG. 7 is configured to perform a read operation of memory cell 104a.

In some embodiments, the one or more read operations and write operations of FIGS. 8A-8C are applicable to at least one column (COL 1) and one row (Row 1) of selection circuit of selection circuit array 602 and at least one memory cell of memory cell array 104 of FIGS. 5-6, and similar detailed description is therefore omitted.

Timing diagrams 800A, 800B and 800C each include waveforms of a word line signal WLP′ of word line WLP0, a word line signal WLN′ of a word line WLN0, a source line signal SL′ of a source line SL0, and a bit line signal BL′ of a bit line BL.

Timing diagrams 800A, 800B and 800C are variations of corresponding timing diagram 400A, 400B and 400C, and similar detailed description is therefore omitted. For example, in comparison with timing diagrams 400A, 400B and 400C of FIGS. 4A-4C, the source line signal SL′ of the source line SL0 of timing diagrams 800A, 800B and 800C replace the source line signal SLP′ of the source line SLP0 and the source line signal SLN′ of the source line SLN0 of timing diagrams 400A, 400B and 400C, and similar detailed description is therefore omitted. Stated differently, the source line signal SLP′ of the source line SLP0 and the source line signal SLN′ of the source line SLN0 of timing diagrams 400A, 400B and 400C are replaced by the source line signal SL′ of the source line SL0 of timing diagrams 800A, 800B and 800C, and operation of memory circuit 700 is similar to operation of memory circuit 300A, and similar detailed description is therefore omitted for brevity.

In some embodiments, by utilizing at least one of timing diagram 800A, 800B or 800C, memory circuit 700 operates to achieve one or more benefits described herein including the details discussed herein.

Other configurations of timing diagram 800A-800C are within the scope of the present disclosure.

### Table

FIG. 8D is a table 800D of the waveforms of timing diagrams 800A-800C, in accordance with some embodiments.

Table 800D includes values of word line signal WLP′ of word line WLP0, values of word line signal WLN′ of word line WLN0, values of source line signal SL′ of source line SL0, and values of bit line signal BL′ of bit line BL from FIGS. 8A-8C in a tabular form simplified for ease of discussion.

Table 800D further includes values of the cell current Icell for the write operations of timing diagrams 800A-800B, and the read operation of timing diagram 800C, in accordance with some embodiments.

Other configurations of table 800D are within the scope of the present disclosure.

### Memory Circuit

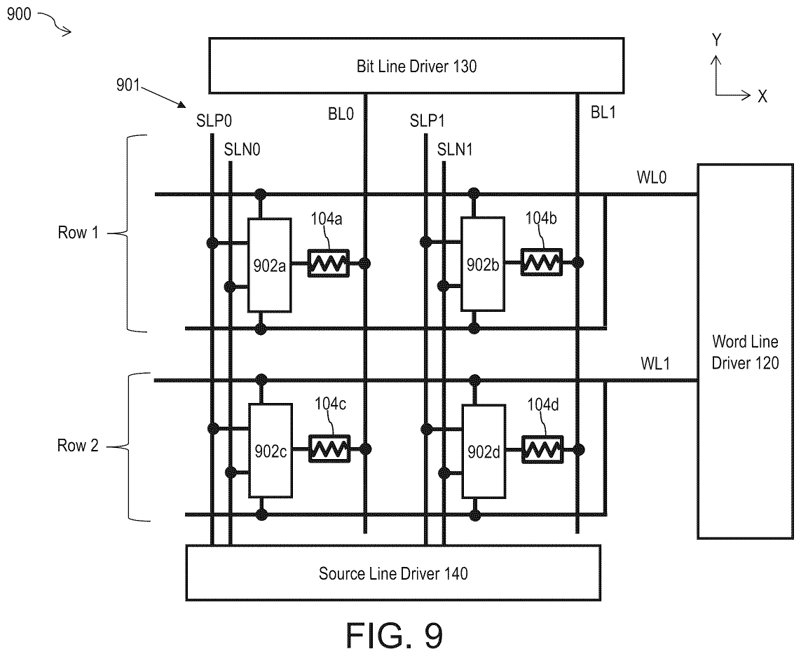

FIG. 9 is a block diagram of a memory circuit 900, in accordance with some embodiments.

Memory circuit 900 is a variation of memory circuit 100 of FIG. 1, and similar detailed description is therefore omitted. For example, memory circuit 900 illustrates a non-limiting example where each selection circuit in selection circuit array 902 is coupled to a single word line (e.g., WL0 or WL1), and similar detailed description is therefore omitted.

Memory circuit 900 includes a selection circuit array 902, memory cell array 104, word lines WL0 and WL1, source lines SLP0 and SLP1, source lines SLN0 and SLN1, bit lines BL0 and BL1, word line driver 120, bit line driver 130, and source line driver 140.

In comparison with FIG. 1, selection circuit array 902 replaces selection circuit array 102, word line WL0 replaces word lines WLP0 and WLN0, and word line WL1 replaces word lines WLP1 and WLN1, and similar detailed description is therefore omitted.

Selection circuit array 902 includes selection circuits 902a, 902b, 902c and 902d.

In comparison with FIG. 1, selection circuits 902a, 902b, 902c and 902d replace corresponding selection circuits 102a, 102b, 102c and 102d, and similar detailed description is therefore omitted.

For case of illustration, selection circuit array 902 is shown as having 2 rows and 2 columns, but other numbers of rows or columns are within the scope of the present disclosure. The number of rows in selection circuit array 902 is equal to or greater than 1. The number of columns in selection circuit array 902 is equal to or greater than 1.

In some embodiments, each selection circuit 902a, 902b, 902c or 902d in selection circuit array 902 includes a pair of transistors in a CFET. Different types of selection circuits in selection circuit array 902 are within the contemplated scope of the present disclosure.

Other configurations of the selection circuit array 902 are within the scope of the present disclosure.

Memory circuit 900 includes M word lines WL0, . . . WL1 (collectively referred to as “word line WL”). Each row 1, . . . , M in selection circuit array 902 is overlapped and coupled to a corresponding word line WL0, . . . WL1. Each word line WL extends in the first direction X and over a row of selection circuits (e.g., row 1, . . . , M).

In some embodiments, the selection circuit array 902, the memory cell array 104, the source lines SLP and SLN, bit line BL and word line WL are also referred to as an array circuit 901.

Other configurations of the source lines SLP and SLN, bit line BL or word line WL are within the scope of the present disclosure.

In some embodiments, memory circuit 900 also includes other circuits (e.g., timing circuits, etc.) that are not described for simplicity.

In some embodiments, memory circuit 900 operates to achieve one or more benefits described herein including the details discussed herein.

Other configurations of memory circuit 900 are within the scope of the present disclosure.

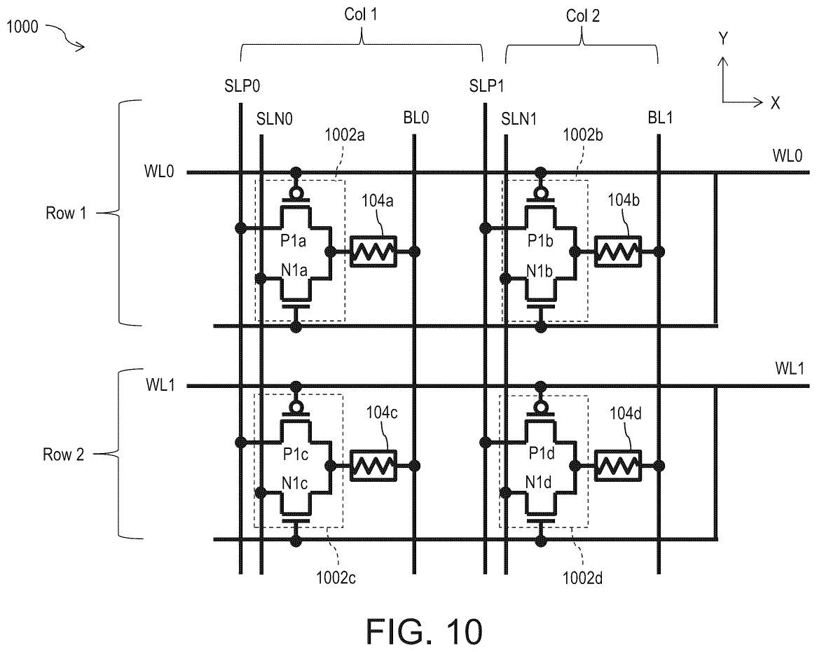

FIG. 10 is a block diagram of a memory circuit 1000, in accordance with some embodiments.

Memory circuit 1000 is a variation of memory circuit 200 of FIG. 2, and similar detailed description is therefore omitted. For example, memory circuit 1000 illustrates a non-limiting example where each selection circuit in selection circuit array 1002 is coupled to a single word line (e.g., WL0 and WL1), and similar detailed description is therefore omitted.

Memory circuit 1000 is an embodiment of the array circuit 901 of FIG. 9, and similar detailed description is therefore omitted. For example, memory circuit 1000 illustrates a non-limiting example where each selection circuit 1002a, 1002b, 1002c or 1002d includes a corresponding P-type transistor (P1a, P1b, P1c or P1d) and a corresponding N-type transistor (N1a, N1b, N1c or N1d).

In some embodiments, selection circuit 1002a, 1002b, 1002c or 1002d of memory circuit 1000 is usable as corresponding selection circuit 902a, 902b, 902c or 902d in selection circuit array 902 in FIG. 9, and similar detailed description is therefore omitted.

Memory circuit 1000 includes a selection circuit array 1002, memory cell array 104, word lines WL0 and WL1, source lines SLP0 and SLP1, source lines SLN0 and SLN1, and bit lines BL0 and BL1.

Selection circuit array 1002 includes selection circuits 1002a, 1002b, 1002c and 1002d.

Selection circuit array 1002 is a variation of selection circuit array 202 of FIG. 2, and similar detailed description is therefore omitted. In comparison with FIG. 2, selection circuits 1002a, 1002b, 1002c and 1002d of selection circuit array 1002 replace corresponding selection circuits 202a, 202b, 202c and 202d of selection circuit array 202, and similar detailed description is therefore omitted.

Selection circuit 1002a includes transistor P1a and transistor N1a.

Selection circuit 1002b includes transistor P1b and transistor N1b.

Selection circuit 1002c includes transistor P1c and transistor N1c.

Selection circuit 1002d includes transistor P1d and transistor N1d.

In FIG. 10, each of the gate terminal of transistor P1a, the gate terminal of transistor P1b, the gate terminal of transistor N1a, the gate terminal of transistor N1b and the word line WL0 are coupled together.

In FIG. 10, each of the gate terminal of transistor P1c, the gate terminal of transistor P1d, the gate terminal of transistor N1c, the gate terminal of transistor N1d and the word line WL1 are coupled together.

Other configurations of the selection circuit array 1002 are within the scope of the present disclosure.

Other configurations of the source lines SLP and SLN, bit line BL or word line WL are within the scope of the present disclosure.

In some embodiments, memory circuit 1000 also includes other circuits (e.g., timing circuits, etc.) that are not described for simplicity.

In some embodiments, memory circuit 1000 operates to achieve one or more benefits described herein including the details discussed herein.

Other configurations of memory circuit 1000 are within the scope of the present disclosure.

### Selection Circuit and Memory Cell

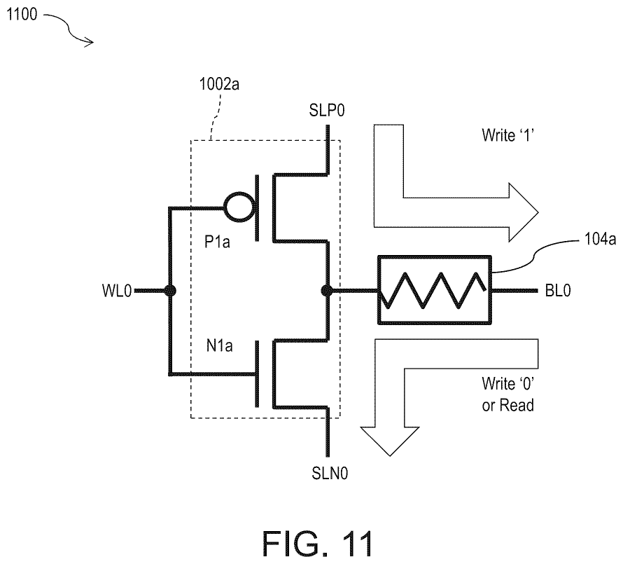

FIG. 11 is a circuit diagram of a memory circuit 1100, in accordance with some embodiments.

Memory circuit 1100 is one column (COL 1) and one row (Row 1) of memory circuit 1000 of FIG. 10, and similar detailed description is therefore omitted. For example, memory circuit 1100 illustrates a non-limiting example of one column (COL 1) and one row (Row 1) of the selection circuit 1002a of selection circuit array 1002 and one column (COL 1) and one row (Row 1) of the memory cell 104a of memory cell array 104 of FIGS. 9-10, and similar detailed description is therefore omitted.

In some embodiments, memory circuit 1100 corresponds to at least one of other rows or other columns in memory circuit 1000, and similar detailed description is therefore omitted.

Memory circuit 1100 includes selection circuit 1002a, memory cell 104a, word line WL0, source lines SLP0 and SLN0, and bit line BL0.

Selection circuit 1002a includes transistor P1a and transistor N1a.

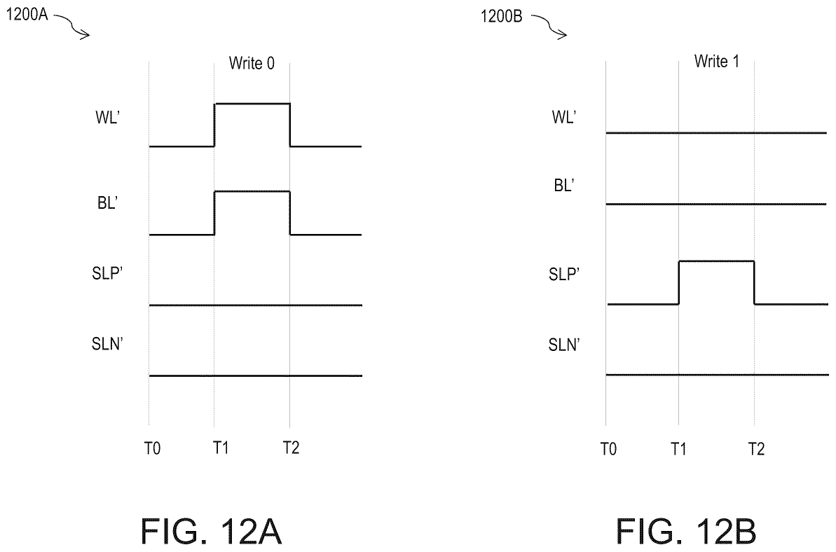

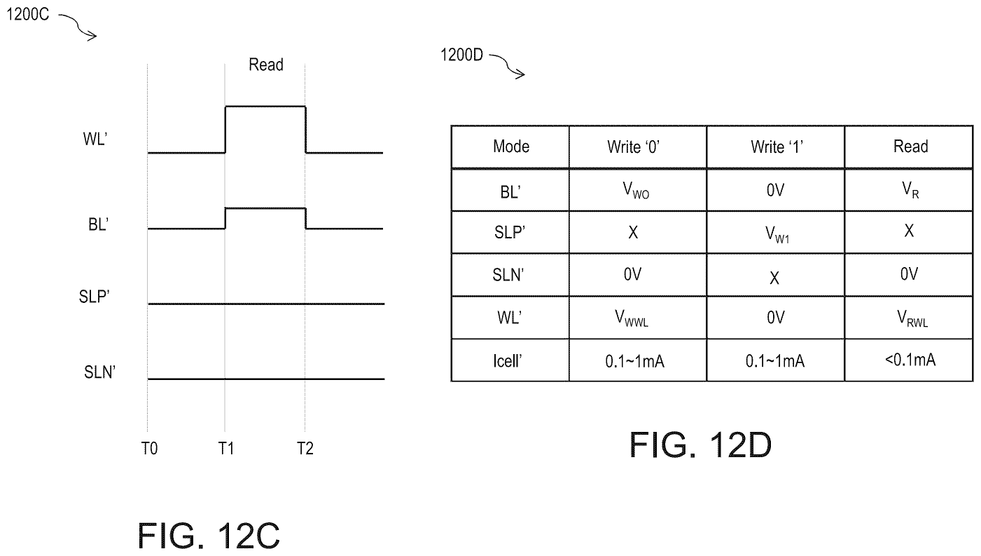

As shown in FIG. 11, transistor P1a is configured to write the first logical value (e.g., logic 1) to memory cell 104a, in accordance with some embodiments. Details of write operations and read operations of memory cell 104a by selection circuit 1002a are described below in FIGS. 12A-12D.

As shown in FIG. 11, transistor N1a is configured to write the second logical value (e.g., logic 0) to memory cell 104a.

As shown in FIG. 11, transistor N1a is configured to perform a read operation of memory cell 104a.

In some embodiments, memory circuit 1100 operates to achieve one or more benefits described herein including the details discussed herein.

Other configurations of memory circuit 1100 are within the scope of the present disclosure.

### Waveforms

FIGS. 12A-12C is a corresponding timing diagram 1200A-1200C of waveforms of a memory circuit 1100, in accordance with some embodiments.

In some embodiments, FIGS. 12A-12C is a corresponding timing diagram 1200A-1200C of waveforms of memory circuit 900 in FIG. 9 or memory circuit 1000 in FIG. 10, in accordance with some embodiments.

In some embodiments, timing diagram 1200A includes waveforms of signals when transistor N1a of FIG. 11 is configured to write the second logical value (e.g., logic 0) to memory cell 104a.

In some embodiments, timing diagram 1200B includes waveforms of signals when transistor P1a of FIG. 11 is configured to write the first logical value (e.g., logic 1) to memory cell 104a.

In some embodiments, timing diagram 1200C includes waveforms of signals when transistor N1a of FIG. 11 is configured to perform a read operation of memory cell 104a.

In some embodiments, the one or more read operations and write operations of FIGS. 12A-12C are applicable to at least one column (COL 1) and one row (Row 1) of selection circuit of selection circuit array 202 and at least one memory cell of memory cell array 104 of FIGS. 1-2, and similar detailed description is therefore omitted.

Timing diagram 1200A, 1200B and 1200C each include waveforms of a word line signal WL′ of word line WL, a source line signal SLP′ of a source line SLP0, a source line signal SLN′ of a source line SLN0, and a bit line signal BL′ of a bit line BL.

At time T0 in FIG. 12A, each of the source line signal SLP′, the source line signal SLN′ and the bit line signal BL′ is logically low.

At time T1 in FIG. 12A, the word line signal WL′ transitions from logically low to a voltage V_{WWL} thereby causing transistor N1a to turn on, and the bit line signal BL′ transitions from logically low to a voltage V_{W0}. For example, at time T1, in response to the word line signal WL′ transitioning from logically low to the voltage V_{WWL}, and the source line signal SLN′ being logically low, the gate to source voltage VGS of transistor N1a is greater than a threshold voltage Vth of transistor N1a thereby causing transistor N1a to turn on, and thus coupling the source line SLN to the first end ND1 of memory cell 104a. In some embodiments, in response to the source line SLN being coupled to the first end ND1 of memory cell 104a by transistor N1a, and the bit line voltage being set at voltage V_{W0}, transistor N1a is configured to write the second logical value (e.g., logic 0) to memory cell 104a.

Furthermore, at time T1 in FIG. 12A, transistor P1a is configured to turn off in response to the source line signal SLP′ being logically low and the word line signal WL′ transitioning from logically low to the voltage V_{WWL}. For example, at time T1, in response to the word line signal WL′ transitioning from logically low to the voltage V_{WWL}, and the source line signal SLP′ being logically low, the gate to source voltage VGS of transistor P1a is greater than a negative threshold voltage −Vth of transistor P1a thereby causing transistor P1a to turn off, and thus decoupling the source line SLP from the first end ND1 of memory cell 104a.

At time T2 in FIG. 12A, the word line signal WL′ transitions from voltage V_{WWL} to logically low thereby causing transistor N1a to turn off, and the bit line signal BL′ transitions from voltage V_{W0} to logically low.

In some embodiments, by utilizing timing diagram 1200A, at least one of memory circuit 1100 operates to achieve one or more benefits described herein including the details discussed herein.

Other configurations of timing diagram 1200A are within the scope of the present disclosure.

FIG. 12B is a timing diagram 1200B of waveforms of a memory circuit 1100, in accordance with some embodiments.

In some embodiments, FIG. 12B is a timing diagram 1200B of waveforms of memory circuit 900 in FIG. 9 or memory circuit 1000 in FIG. 10, in accordance with some embodiments.

In some embodiments, timing diagram 1200B includes waveforms of signals when transistor P1a of FIG. 11 is configured to write the first logical value (e.g., logic 1) to memory cell 104b.

At time T0 in FIG. 12B, each of the word line signal WL′, the source line signal SLP′, the source line signal SLN′ and the bit line signal BL′ is logically low.

At time T1 in FIG. 12B, the source line signal SLP′ transitions from logically low to the voltage V_{W1}, thereby causing transistor P1a to turn on. For example, at time T1, in response to the word line signal WL′ being logically low, and the source line signal SLP′ transitioning to voltage V_{W1}, the gate to source voltage VGS of transistor P1a is less than the negative threshold voltage −Vth of transistor P1a, thus turning on transistor P1a and coupling the source line SLP to the first end ND1 of memory cell 104b. In some embodiments, in response to the source line SLP being coupled to the first end ND1 of memory cell 104b by transistor P1a, and the bit line voltage being set at logically low, transistor P1a is configured to write the first logical value (e.g., logic 1) to memory cell 104b.

At time T1 in FIG. 12B, the source line signal SLN′ is logically low, thereby causing transistor N1a to turn off. For example, at time T1, in response to the word line signal WL′ being logically low, and the source line signal SLN′ being logically low, the gate to source voltage VGS of transistor N1a is less than the threshold voltage Vth of transistor N1a thereby causing transistor N1a to turn off, and thus decoupling the source line SLN from the first end ND1 of memory cell 104b.

At time T2 in FIG. 12B, the source line signal SLP′ transitions from voltage V_{W1} to logically low, thereby causing transistor P1a to turn off.

In some embodiments, by utilizing timing diagram 1200B, at least one of memory circuit 1100 operates to achieve one or more benefits described herein including the details discussed herein.

Other configurations of timing diagram 1200B are within the scope of the present disclosure.

FIG. 12C is a timing diagram 1200C of waveforms of a memory circuit 1100, in accordance with some embodiments.

In some embodiments, FIG. 12C is a timing diagram 1200C of waveforms of memory circuit 900 in FIG. 9 or memory circuit 1000 in FIG. 10, in accordance with some embodiments.

In some embodiments, timing diagram 1200C includes waveforms of signals when transistor N1a of FIG. 11 is configured to perform a read operation of memory cell 104a.

At time T0 in FIG. 12C, each of the word line signal WL′, the source line signal SLP′, the source line signal SLN′ and the bit line signal BL′ is logically low.

At time T1 in FIG. 12C, the word line signal WL′ transitions from logically low to a voltage V_{RWL} thereby causing transistor N1a to turn on, and the bit line signal BL′ transitions from logically low to a voltage V_{R}. For example, at time T1, in response to the word line signal WL′ transitioning from logically low to the voltage V_{RWL}, and the source line signal SLN′ being logically low, the gate to source voltage VGS of transistor N1a is greater than a threshold voltage Vth of transistor N1a thereby causing transistor N1a to turn on, and thus coupling the source line SLN to the first end ND1 of memory cell 104a. In some embodiments, in response to the source line SLN being coupled to the first end ND1 of memory cell 104a by transistor N1a, and the bit line voltage being set at voltage V_{R}, transistor N1a is configured to read the data stored in memory cell 104a.

Furthermore, at time T1 in FIG. 12C, transistor P1a is configured to turn off in response to the source line signal SLP′ being logically low and the word line signal WL′ transitioning from logically low to the voltage V_{RWL}. For example, at time T1, in response to the word line signal WL′ transitioning from logically low to the voltage V_{RWL}, and the source line signal SLP′ being logically low, the gate to source voltage VGS of transistor P1a is greater than a negative threshold voltage −Vth of transistor P1a thereby causing transistor P1a to turn off, and thus decoupling the source line SLP from the first end ND1 of memory cell 104a.

At time T2 in FIG. 12C, the word line signal WL′ transitions from voltage V_{RWL} to logically low thereby causing transistor N1a to turn off, and the bit line signal BL′ transitions from voltage V_{R} to logically low.

In some embodiments, by utilizing timing diagram 1200C, at least one of memory circuit 1100 operates to achieve one or more benefits described herein including the details discussed herein.

Other configurations of timing diagram 1200C are within the scope of the present disclosure.

### Table

FIG. 12D is a table 1200D of the waveforms of timing diagrams 1200A-1200C, in accordance with some embodiments.

Table 1200D includes values of word line signal WLP′ of word line WLP0, values of source line signal SLP′ of source line SLP0, values of source line signal SLN′ of source line SLN0, and values of bit line signal BL′ of bit line BL from FIGS. 12A-12C in a tabular form simplified for case of discussion.

Table 1200D further includes values of a cell current Icell for the write operations of timing diagrams 1200A-1200B, and the read operation of timing diagram 1200C, in accordance with some embodiments.

Other configurations of table 1200D are within the scope of the present disclosure.

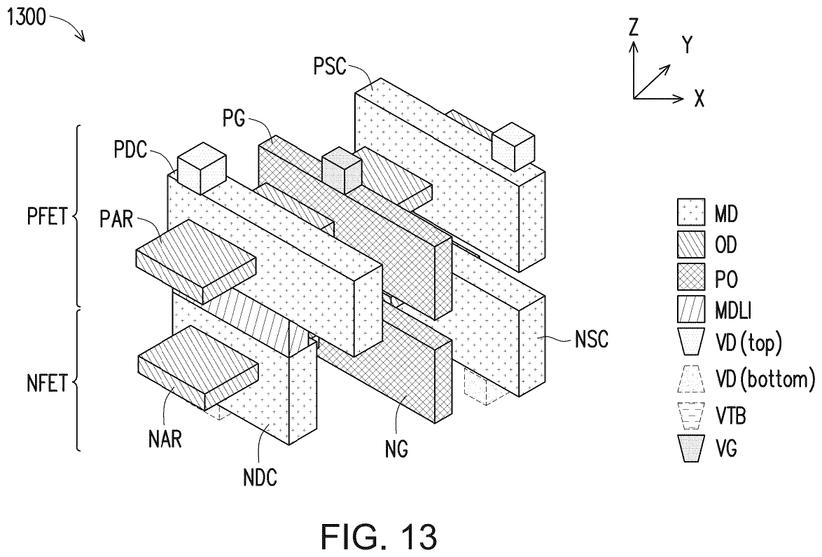

FIG. 13 is a perspective view of a diagram of an integrated circuit 1300, in accordance with some embodiments.

Integrated circuit 1300 is at least one of selection circuit 102a, 102b, 102c, 102d, 202a, 202b, 202c, 202d, 302a, 302b, 502a, 502b, 502c, 502d, 602a, 602b, 602c, 602d, 902a, 902b, 902c, 902d, 1002a, 1002b, 1002c or 1002d.

Integrated circuit 1300 includes an active region PAR and an active region NAR. In some embodiments, active region PAR is the active region of at least one of transistor P1a, P1b, P1c, P1d or P2a, and active region NAR is the active region of at least one of transistor N1a, N1b, N1c, N1d or N2a.

Integrated circuit 1300 further includes a gate PG and a gate NG. In some embodiments, gate PG is the gate of at least one of transistor P1a, P1b, P1c, P1d or P2a, and gate NG is the gate of at least one of transistor N1a, N1b, N1c, N1d or N2a.

Integrated circuit 1300 further includes a contact PDC, a contact PSC, a contact NDC and a contact NSC. In some embodiments, contact PDC is a drain contact of at least one of transistor P1a, P1b, P1c, P1d or P2a, contact PSC is a source contact of at least one of transistor P1a, P1b, P1c, P1d or P2a, contact NDC is a drain contact of at least one of transistor N1a, N1b, N1c, N1d or N2a, and contact NSC is a source contact of at least one of transistor N1a, N1b, N1c, N1d or N2a.

Integrated circuit 1300 includes a PFET transistor and an NFET transistor. In some embodiments, the PFET transistor corresponds to at least one of transistor P1a, P1b, P1c, P1d or P2a. In some embodiments, the NFET transistor corresponds to at least one of transistor N1a, N1b, N1c, N1d or N2a.

In some embodiments, the PFET transistor and the NFET transistor are on separate levels. In some embodiments, the PFET transistor is on a first level, and the NFET transistor is on a second level. In some embodiments, the first level is different from the second level. In some embodiments, the first level is above the second level. In some embodiments, the first level is below the second level. In some embodiments, the first level is the same as the second level.

Other configurations of memory circuit 1300 are within the scope of the present disclosure.

### Method:

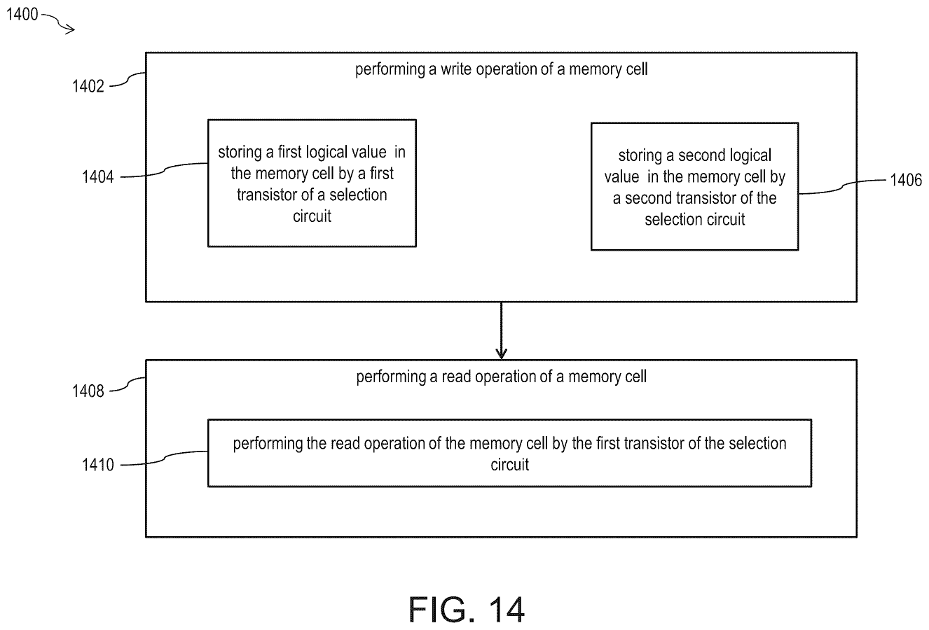

FIG. 14 is a flowchart of a method 1400 of operating a circuit, in accordance with some embodiments.

In some embodiments, FIG. 14 is a flowchart of a method 1400 of operating at least one of memory circuit 100 of FIG. 1, memory circuit 200 of FIG. 2, memory circuit 300A-300C of FIGS. 3A-3C, memory circuit 500 of FIG. 5, memory circuit 600 of FIG. 6, memory circuit 700 of FIG. 7, memory circuit 900 of FIG. 9, memory circuit 1000 of FIG. 10, or memory circuit 1100 of FIG. 11.

In some embodiments, FIG. 14 is a flowchart of a method 1400 of operating a memory circuit, and the method 1400 includes the features of timing diagrams 400A-400C of FIGS. 4A-4C, timing diagrams 800A-800C of FIGS. 8A-8C, or timing diagrams 1200A-1200C of FIGS. 12A-12C, and similar detailed description is omitted for brevity.

In some embodiments, FIG. 14 is a flowchart of a method 1400 of operating a memory circuit, and the method 1400 includes the features of table 400D of FIG. 4D, table 800D of FIG. 8D, or table 1200D of FIG. 12D, and similar detailed description is omitted for brevity.

It is understood that additional operations may be performed before, during, and/or after the method 1400 depicted in FIG. 14, and that some other operations may only be briefly described herein. It is understood that method 1400 utilizes features of one or more of least one of memory circuit 100 of FIG. 1, memory circuit 200 of FIG. 2, memory circuit 300A-300C of FIGS. 3A-3C, memory circuit 500 of FIG. 5, memory circuit 600 of FIG. 6, memory circuit 700 of FIG. 7, memory circuit 900 of FIG. 9, memory circuit 1000 of FIG. 10, or memory circuit 1100 of FIG. 11, and similar detailed description is omitted for brevity.

In some embodiments, other order of operations of method 1400 is within the scope of the present disclosure. Method 1400 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 1400 is not performed.

In operation 1402 of method 1400, a write operation of a memory cell is performed. In some embodiments, operation 1402 is performed by a first transistor of a selection circuit or a second transistor of the selection circuit.

In some embodiments, the first transistor includes at least one of transistor N1a, N1b, N1c, N1d or N2a. In some embodiments, the second transistor includes at least one of transistor P1a, P1b, P1c, P1d or P2a.

In some embodiments, the selection circuit includes at least one of selection circuit 102a, 102b, 102c, 102d, 202a, 202b, 202c, 202d, 302a, 302b, 502a, 502b, 502c, 502d, 602a, 602b, 602c, 602d, 902a, 902b, 902c, 902d, 1002a, 1002b, 1002c or 1002d.

In some embodiments, the memory cell includes at least one of memory cell 104a, 104b, 104c or 104d.

In some embodiments, operation 1402 of method 1400 includes at least one of operation 1404 or operation 1406.

In operation 1404 of method 1400, a first logical value (e.g., write 0) is stored in the memory cell by the first transistor of the selection circuit. In some embodiments, the first logical value is a logic 0. In some embodiments, the selection circuit is coupled to the memory cell.

In operation 1406 of method 1400, a second logical value (e.g., write 1) is stored in the memory cell by the second transistor of the selection circuit. In some embodiments, the second logical value is a logic 1. In some embodiments, the selection circuit is coupled to the memory cell.

In operation 1408 of method 1400, a read operation of the memory cell is performed. In some embodiments, operation 1408 is performed by the first transistor of the selection circuit.

In some embodiments, operation 1408 of method 1400 includes operation 1410.

In operation 1410 of method 1400, the read operation of the memory cell is performed by the first transistor of the selection circuit.

### Method:

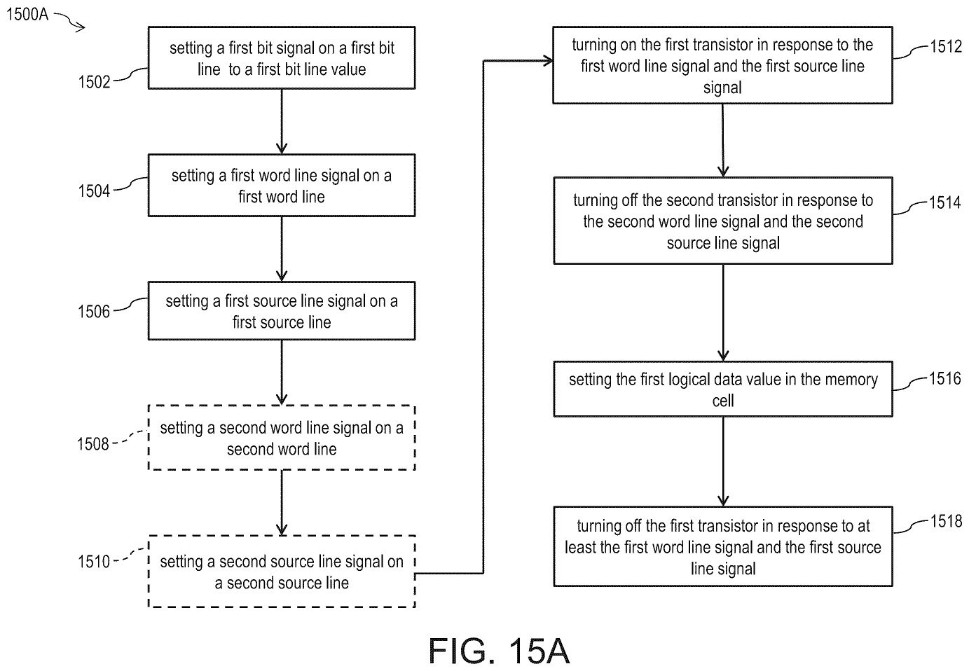

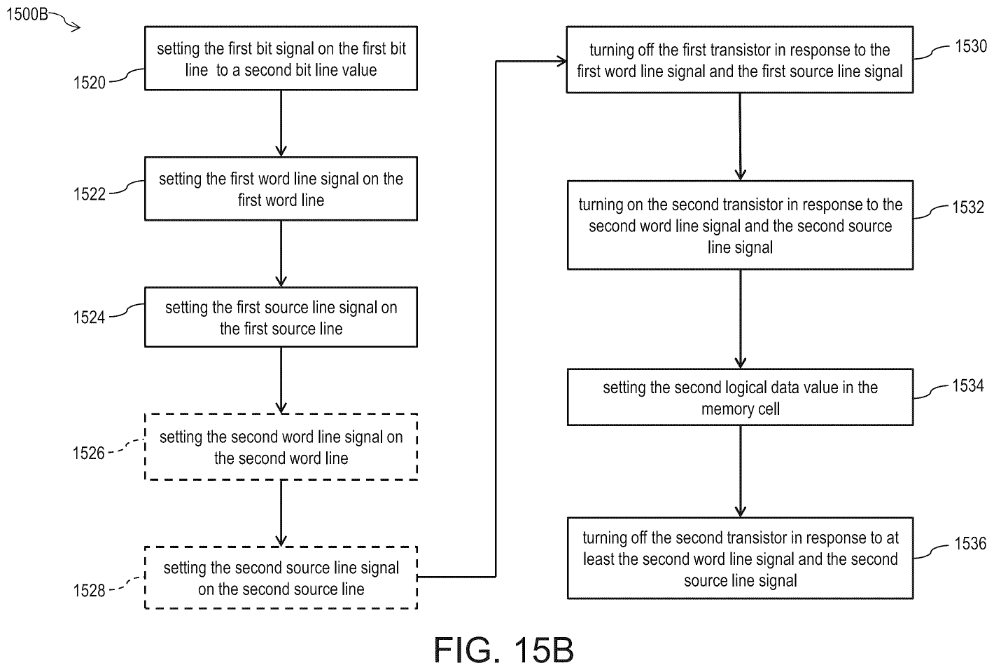

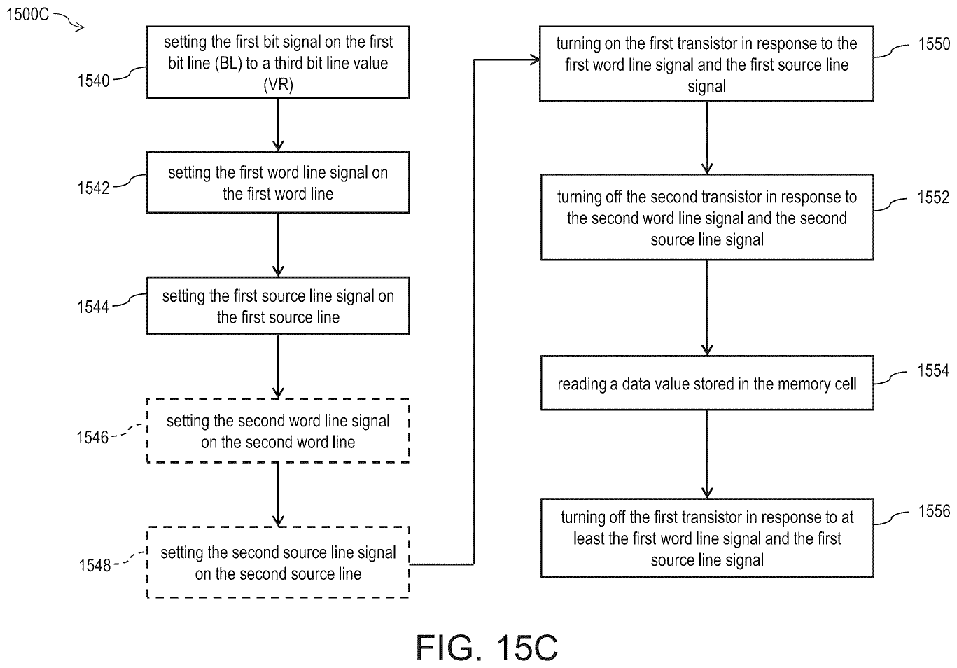

FIGS. 15A-15C are a flowchart of methods 1500A-1500C of operating a circuit, in accordance with some embodiments.

In some embodiments, method 1500A is an embodiment of at least operation 1404 of method 1400, and similar detailed description is omitted for brevity.

In some embodiments, method 1500B is an embodiment of at least operation 1406 of method 1400, and similar detailed description is omitted for brevity.

In some embodiments, method 1500C is an embodiment of at least operation 1410 of method 1400, and similar detailed description is omitted for brevity.

In some embodiments, FIGS. 15A-15C are flowcharts of methods 1500A-1500C of operating at least one of memory circuit 100 of FIG. 1, memory circuit 200 of FIG. 2, memory circuit 300A-300C of FIGS. 3A-3C, memory circuit 500 of FIG. 5, memory circuit 600 of FIG. 6, memory circuit 700 of FIG. 7, memory circuit 900 of FIG. 9, memory circuit 1000 of FIG. 10, or memory circuit 1100 of FIG. 11.

In some embodiments, FIGS. 15A-15C are flowcharts of methods 1500A-1500C of operating a memory circuit, and the methods 1500A-1500C include the features of timing diagrams 400A-400C of FIGS. 4A-4C, timing diagrams 800A-800C of FIGS. 8A-8C, or timing diagrams 1200A-1200C of FIGS. 12A-12C, and similar detailed description is omitted for brevity.

In some embodiments, FIGS. 15A-15C are a flowchart of a method 1400 of operating a memory circuit, and the method 1400 includes the features of table 400D of FIG. 4D, table 800D of FIG. 8D, or table 1200D of FIG. 12D, and similar detailed description is omitted for brevity.

It is understood that additional operations may be performed before, during, and/or after methods 1500A-1500C depicted in FIGS. 15A-15C, and that some other operations may only be briefly described herein. It is understood that methods 1500A-1500C utilize features of one or more of least one of memory circuit 100 of FIG. 1, memory circuit 200 of FIG. 2, memory circuit 300A-300C of FIGS. 3A-3C, memory circuit 500 of FIG. 5, memory circuit 600 of FIG. 6, memory circuit 700 of FIG. 7, memory circuit 900 of FIG. 9, memory circuit 1000 of FIG. 10, or memory circuit 1100 of FIG. 11, and similar detailed description is omitted for brevity.

In some embodiments, other order of operations of methods 1500A-1500C are within the scope of the present disclosure. Methods 1500A-1500C includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of methods 1500A-1500C is not performed.

In some embodiments, common elements in at least one of method 1500A, 1500B or 1500C are not labelled in the description of each individual method 1500A, 1500B or 1500C for brevity.

In some embodiments, the values of signals during one or more operations of method 1500A-1500C are according to the values shown in Table 400D, 800D and 1200D.

In operation 1502 of method 1500A, a first bit line signal on a first bit line (BL) is set to a first bit line value (e.g., logic 1), the first bit line being coupled to the memory cell.

In some embodiments, operation 1502 is performed by the bit line driver 130.

In some embodiments, the first bit line signal is bit line signal BL′.

In some embodiments, the first bit line includes one or more of bit lines BL.

In some embodiments, the first bit line value is equal to voltage V_{W0}.

In some embodiments, the memory cell includes at least one of memory cell 104a, 104b, 104c or 104d.

In operation 1504 of method 1500A, a first word line signal on a first word line is set. In some embodiments, the first word line is coupled to at least a first transistor or a second transistor of the selection circuit.

In some embodiments, operation 1504 is performed by the word line driver 120.

In some embodiments, the first word line signal is word line signal WLP′ or WL′.

In some embodiments, the first word line includes one or more of word lines WLP, WLP0a, WLN0a or WL.

In some embodiments, the first word line is set to a first word line value. In some embodiments, the first word line value is equal to a logic 0.

In some embodiments, the first transistor includes at least one of transistor N1a, N1b, N1c, N1d or N2a. In some embodiments, the second transistor includes at least one of transistor P1a, P1b, P1c, P1d or P2a.

In some embodiments, the selection circuit includes at least one of selection circuit 102a, 102b, 102c, 102d, 202a, 202b, 202c, 202d, 302a, 302b, 502a, 502b, 502c, 502d, 602a, 602b, 602c, 602d, 902a, 902b, 902c, 902d, 1002a, 1002b, 1002c or 1002d.

In operation 1506 of method 1500A, a first source line signal on a first source line (SLP, SLN or SL) is set. In some embodiments, the first source line being coupled to at least the first transistor or the second transistor.

In some embodiments, operation 1506 is performed by the source line driver 140.

In some embodiments, the first source line signal is source line signal SLP′ or SL′.

In some embodiments, the first source line includes one or more of source lines SLP or SL.

In some embodiments, the first source line is set to a first source line value. In some embodiments, the first source line value is equal to a logic 0.

In operation 1508 of method 1500A, a second word line signal on a second word line is set.

In some embodiments, the second word line is coupled to the second transistor.

In some embodiments, operation 1508 is performed by the word line driver 120.

In some embodiments, the second word line signal is word line signal WLN′ or WL′.

In some embodiments, the second word line includes one or more of word lines WLN, WLP0a, WLN0a or WL.

In some embodiments, the second word line is set to a second word line value. In some embodiments, the second word line value is equal to a voltage V_{WWL}.

In operation 1510 of method 1500A, a second source line signal on a second source line is set. In some embodiments, the second source line is coupled to the second transistor.

In some embodiments, operation 1510 is performed by the source line driver 140.

In some embodiments, the second source line signal is source line signal SLN′ or SL′.

In some embodiments, the second source line includes one or more of source lines SLN or SL.

In some embodiments, the second source line is set to a second source line value. In some embodiments, the second source line value is equal to a logic 0.

In operation 1512 of method 1500A, the first transistor is turned on in response to the first word line signal and the first source line signal thereby electrically coupling the first source line to a first end ND1 of the memory cell.

In operation 1514 of method 1500A, the second transistor is turned off in response to the second word line signal and the second source line signal thereby electrically decoupling the second source line from the first end of the memory cell.

In operation 1516 of method 1500A, the first logical value (e.g., logic 0) is set as a value stored in the memory cell.

In operation 1518 of method 1500A, the first transistor is turned off in response to at least the first word line signal and the first source line signal thereby electrically decoupling the first source line from the first end of the memory cell.

In some embodiments, while method 1500A is described with respect to memory circuit 300, method 1500A is also applicable to at least one of memory circuit 700 or 1100 in a similar manner and is not described for brevity. For example, in some embodiments, when method 1500A is applied to memory circuit 700, at least operation 1510 is not performed, and the second source line is the first source line, as described in FIGS. 5-8D, and similar detailed description is therefore omitted. For example, in some embodiments, when method 1500A is applied to memory circuit 1100, at least operation 1508 is not performed, and the second word line is the first word line, as described in FIGS. 9-12D, and similar detailed description is therefore omitted.

In operation 1520 of method 1500B, the first bit line signal on the first bit line (BL) is set to a second bit line value (e.g., logic 0).

In some embodiments, operation 1520 is performed by the bit line driver 130.

In some embodiments, the second bit line value is equal to logic 0.

FIG. 15B is a flowchart of method 1500B of operating a circuit, in accordance with some embodiments. In some embodiments, method 1500B is an embodiment of at least operation 1406 of method 1400, and similar detailed description is omitted for brevity.

In operation 1522 of method 1500B, the first word line signal on the first word line is set.

In some embodiments, operation 1522 is performed by the word line driver 120.

In some embodiments, the first word line is set to a first word line value. In some embodiments, the first word line value is equal to a logic 0.

In operation 1524 of method 1500B, the first source line signal on the first source line (SLP, SLN or SL) is set.

In some embodiments, operation 1524 is performed by the source line driver 140.

In some embodiments, the first source line is set to a first source line value. In some embodiments, the first source line value is equal to voltage V_{W1}.

In operation 1526 of method 1500B, a second word line signal on a second word line is set.

In some embodiments, operation 1526 is performed by the word line driver 120.

In some embodiments, the second word line signal is word line signal WLN′ or WL′.

In some embodiments, the second word line includes one or more of word lines WLN, WLP0a, WLN0a or WL.

In some embodiments, the second word line is set to a second word line value. In some embodiments, the second word line value is equal to a voltage V_{WWL}.

In operation 1528 of method 1500B, a second source line signal on a second source line is set.

In some embodiments, operation 1528 is performed by the source line driver 140.

In some embodiments, the second source line signal is source line signal SLN′ or SL′.

In some embodiments, the second source line includes one or more of source lines SLN or SL.

In some embodiments, the second source line is set to a second source line value. In some embodiments, the second source line value is equal to voltage V_{W1}.

In operation 1530 of method 1500B, the first transistor is turned off in response to the first word line signal and the first source line signal thereby electrically decoupling the first source line from the first end ND1 of the memory cell.

In operation 1532 of method 1500B, the second transistor is turned on in response to the second word line signal and the second source line signal thereby electrically coupling the second source line to the first end of the memory cell.

In operation 1534 of method 1500B, the second logical value (e.g., logic 1) is set as a value stored in the memory cell.

In operation 1536 of method 1500B, the second transistor is turned off in response to at least the second word line signal and the second source line signal thereby electrically decoupling the second source line from the first end of the memory cell.

In some embodiments, while method 1500B is described with respect to memory circuit 300, method 1500B is also applicable to at least one of memory circuit 700 or 1100 in a similar manner and is not described for brevity. For example, in some embodiments, when method 1500B is applied to memory circuit 700, at least operation 1528 is not performed, and the second source line is the first source line, as described in FIGS. 5-8D, and similar detailed description is therefore omitted. For example, in some embodiments, when method 1500B is applied to memory circuit 1100, at least operation 1526 is not performed, and the second word line is the first word line, as described in FIGS. 9-12D, and similar detailed description is therefore omitted.

FIG. 15C is a flowchart of method 1500C of operating a circuit, in accordance with some embodiments. In some embodiments, method 1500C is an embodiment of at least operation 1410 of method 1400, and similar detailed description is omitted for brevity.

In operation 1540 of method 1500C, the first bit line signal on the first bit line (BL) is set to a third bit line value (e.g., voltage V_{R}).

In some embodiments, operation 1540 is performed by the bit line driver 130.

In some embodiments, the first bit line signal is bit line signal BL′.

In some embodiments, the first bit line includes one or more of bit lines BL.

In some embodiments, the first bit line value is equal to voltage V_{R}.

In operation 1542 of method 1500C, the first word line signal on the first word line is set.

In some embodiments, operation 1542 is performed by the word line driver 120.

In some embodiments, the first word line signal is word line signal WLP′ or WL′.

In some embodiments, the first word line includes one or more of word lines WLP, WLP0a, WLN0a or WL.

In some embodiments, the first word line is set to a first word line value. In some embodiments, the first word line value is equal to a logic 0.

In operation 1544 of method 1500C, a first source line signal on a first source line (SLP, SLN or SL) is set.

In some embodiments, operation 1544 is performed by the source line driver 140.

In some embodiments, the first source line signal is source line signal SLP′ or SL′.

In some embodiments, the first source line includes one or more of source lines SLP or SL.

In some embodiments, the first source line is set to a first source line value. In some embodiments, the first source line value is equal to a logic 0.

In operation 1546 of method 1500C, a second word line signal on a second word line is set.

In some embodiments, operation 1546 is performed by the word line driver 120.

In some embodiments, the second word line signal is word line signal WLN′ or WL′.

In some embodiments, the second word line includes one or more of word lines WLN, WLP0a, WLN0a or WL.

In some embodiments, the second word line is set to a second word line value. In some embodiments, the second word line value is equal to a voltage V_{RWL}.

In operation 1548 of method 1500C, a second source line signal on a second source line is set.

In some embodiments, operation 1548 is performed by the source line driver 140.

In some embodiments, the second source line signal is source line signal SLN′ or SL′.

In some embodiments, the second source line includes one or more of source lines SLN or SL.

In some embodiments, the second source line is set to a second source line value. In some embodiments, the second source line value is equal to a logic 0.

In operation 1550 of method 1500C, the first transistor is turned on in response to the first word line signal and the first source line signal thereby electrically coupling the first source line to a first end ND1 of the memory cell.

In operation 1552 of method 1500C, the second transistor is turned off in response to the second word line signal and the second source line signal thereby electrically decoupling the second source line from the first end of the memory cell.

In operation 1554 of method 1500C, a data value stored in the memory cell is read.

In operation 1556 of method 1500C, the first transistor is turned off in response to at least the first word line signal and the first source line signal thereby electrically decoupling the first source line from the first end of the memory cell.

In some embodiments, while method 1500C is described with respect to memory circuit 300, method 1500C is also applicable to at least one of memory circuit 700 or 1100 in a similar manner and is not described for brevity. For example, in some embodiments, when method 1500C is applied to memory circuit 700, at least operation 1548 is not performed, and the second source line is the first source line, as described in FIGS. 5-8D, and similar detailed description is therefore omitted. For example, in some embodiments, when method 1500C is applied to memory circuit 1100, at least operation 1546 is not performed, and the second word line is the first word line, as described in FIGS. 9-12D, and similar detailed description is therefore omitted.

By operating at least one of method 1400, 1500A, 1500B or 1500C, the circuit operates to achieve the benefits discussed above with respect to at least one of memory circuit 100 of FIG. 1, memory circuit 200 of FIG. 2, memory circuit 300A-300C of FIGS. 3A-3C, memory circuit 500 of FIG. 5, memory circuit 600 of FIG. 6, memory circuit 700 of FIG. 7, memory circuit 900 of FIG. 9, memory circuit 1000 of FIG. 10, or memory circuit 1100 of FIG. 11, timing diagrams 400A-400C of FIGS. 4A-4C, timing diagrams 800A-800C of FIGS. 8A-8C, or timing diagrams 1200A-1200C of FIGS. 12A-12C, table 400D of FIG. 4D, table 800D of FIG. 8D, or table 1200D of FIG. 12D.

In some embodiments, one or more of the operations of method 1400, 1500A, 1500B or 1500C is not performed. Furthermore, various PMOS or NMOS transistors shown in FIGS. 2, 3A-3C, 6-7 and 10-11 are of a particular dopant type (e.g., N-type or P-type) are for illustration purposes. Embodiments of the disclosure are not limited to a particular transistor type, and one or more of the PMOS or NMOS transistors shown in FIGS. 2, 3A-3C, 6-7 and 10-11 can be substituted with a corresponding transistor of a different transistor/dopant type. Similarly, the low or high logical value of various signals used in the above description is also for illustration. Embodiments of the disclosure are not limited to a particular logical value when a signal is activated and/or deactivated. Selecting different logical values is within the scope of various embodiments. Selecting different numbers of transistors in FIGS. 2, 3A-3C, 6-7 and 10-11 is within the scope of various embodiments.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

One aspect of this description relates to a memory circuit. The memory circuit includes a first bit line; a memory cell coupled to the first bit line; a selection circuit coupled to the memory cell. In some embodiments, the selection circuit includes a first transistor on a first level; and a second transistor on the first level or a second level different from the first level. In some embodiments, the memory circuit further includes a first word line coupled to at least the first transistor or the second transistor, and a first source line coupled to at least the first transistor or the second transistor. In some embodiments, the first transistor and the second transistor are part of a complementary field-effect transistor (CFET). In some embodiments, the first transistor is configured to perform a write operation of the memory cell in response to the memory cell being configured to store a first logical value. In some embodiments, the second transistor is configured to perform a read operation of the memory cell, and the write operation of the memory cell in response to the memory cell being configured to store a second logical value different from the first logical value.

Another aspect of this description relates to a memory circuit. The memory circuit includes a first bit line; a second bit line; and a memory cell array. In some embodiments, a memory cell array includes a first memory cell coupled to the first bit line, and a second memory cell coupled to the second bit line. In some embodiments, the memory circuit further includes a selection circuit array coupled to the memory cell array. In some embodiments, the selection circuit array includes a first selection circuit coupled to the first memory cell. In some embodiments, the first selection circuit includes a first transistor, and a second transistor. In some embodiments, the selection circuit array further includes a second selection circuit coupled to the second memory cell. In some embodiments, the first transistor and the second transistor are part of a complementary field-effect transistor (CFET). In some embodiments, the first transistor is configured to perform a write operation of the first memory cell in response to the first memory cell being configured to store a first logical value. In some embodiments, the second transistor is configured to perform a read operation of the first memory cell, and the write operation of the first memory cell in response to the first memory cell being configured to store a second logical value different from the first logical value.

Still another aspect of this description relates to a method of operating a memory circuit. The method includes performing a write operation of a memory cell. In some embodiments, performing the write operation of the memory cell includes storing a first logical value in the memory cell by a first transistor of a selection circuit, the selection circuit being coupled to the memory cell; or storing a second logical value in the memory cell by a second transistor of the selection circuit, the second logical value being different from the first logical value. In some embodiments, the method further includes performing a read operation of the memory cell by the first transistor of the selection circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a first bit line;
a memory cell coupled to the first bit line;
a selection circuit coupled to the memory cell, the selection circuit comprising:
a first transistor on a first level; and
a second transistor on the first level or a second level different from the first level;
a first word line coupled to at least the first transistor or the second transistor;
a first source line coupled to at least the first transistor or the second transistor;
wherein the first transistor and the second transistor are part of a complementary field-effect transistor (CFET),
the first transistor is configured to perform a write operation of the memory cell in response to the memory cell being configured to store a first logical value, and
the second transistor is configured to perform a read operation of the memory cell, and the write operation of the memory cell in response to the memory cell being configured to store a second logical value different from the first logical value.

2. The memory circuit of claim 1, wherein
the first transistor comprises:
a first gate terminal coupled to the first word line;
a first drain terminal coupled to a first end of the memory cell; and
a first source terminal coupled to the first source line; and
the second transistor comprises:
a second gate terminal;
a second drain terminal coupled to the first drain terminal and the first end of the memory cell; and
a second source terminal.

3. The memory circuit of claim 2, further comprising:
a second word line coupled to the second gate terminal of the second transistor; and
a second source line coupled to the second source terminal of the second transistor.

4. The memory circuit of claim 3, wherein
the first transistor is a first type;
the second transistor is a second type different from the first type; and
the second transistor is on the second level.

5. The memory circuit of claim 3, wherein
the first transistor is a first type;
the second transistor is the first type; and
the second transistor is on the first level.

6. The memory circuit of claim 2, further comprising:
a second word line coupled to the second gate terminal of the second transistor,
wherein the second source terminal of the second transistor is coupled to the first source line.

7. The memory circuit of claim 6, wherein
the first transistor is a first type;
the second transistor is a second type different from the first type; and
the second transistor is on the second level.

8. The memory circuit of claim 2, further comprising:
a second source line coupled to the second source terminal of the second transistor,
wherein the second gate terminal of the second transistor is coupled to the first word line and the first gate terminal.

9. The memory circuit of claim 6, wherein
the first transistor is a first type;
the second transistor is a second type different from the first type; and
the second transistor is on the second level.

10. A memory circuit, comprising:
a first bit line;
a second bit line;
a memory cell array comprising:
a first memory cell coupled to the first bit line; and
a second memory cell coupled to the second bit line;
a selection circuit array coupled to the memory cell array, the selection circuit array comprising:
a first selection circuit coupled to the first memory cell, the first selection circuit comprising:
a first transistor; and
a second transistor;
a second selection circuit coupled to the second memory cell;
wherein the first transistor and the second transistor are part of a complementary field-effect transistor (CFET),
the first transistor is configured to perform a write operation of the first memory cell in response to the first memory cell being configured to store a first logical value, and
the second transistor is configured to perform a read operation of the first memory cell, and the write operation of the first memory cell in response to the first memory cell being configured to store a second logical value different from the first logical value.

11. The memory circuit of claim 10, further comprising:
a first word line coupled to the first memory cell and the second memory cell;
a first source line coupled to at least the first memory cell; and
a second source line coupled to at least the second memory cell.

12. The memory circuit of claim 11, wherein the second selection circuit comprises:
a third transistor; and
a fourth transistor.

13. The memory circuit of claim 12, wherein
the first transistor comprises:
a first gate terminal coupled to the first word line;
a first drain terminal coupled to a first end of the first memory cell; and
a first source terminal coupled to the first source line; and
the second transistor comprises:
a second gate terminal;
a second drain terminal coupled to the first drain terminal and the first end of the first memory cell; and
a second source terminal.

14. The memory circuit of claim 13, wherein
the third transistor comprises:
a third gate terminal coupled to the first word line;
a third drain terminal coupled to a first end of the second memory cell; and
a third source terminal coupled to the second source line; and
the fourth transistor comprises:
a fourth gate terminal;
a fourth drain terminal coupled to the third drain terminal and the first end of the second memory cell; and
a fourth source terminal.

15. The memory circuit of claim 14, further comprising:
a second word line coupled to the second gate terminal of the second transistor and the fourth gate terminal of the fourth transistor;
a third source line coupled to the second source terminal of the second transistor; and
a fourth source line coupled to the fourth source terminal of the fourth transistor.

16. The memory circuit of claim 15, wherein
the first transistor is a first type;
the second transistor is a second type different from the first type;
the third transistor is the first type;
the fourth transistor is the second type;
the first transistor is on a first level;
the second transistor is on a second level different from the first level;
the third transistor is on the first level; and
the fourth transistor is on the second level.

17. The memory circuit of claim 14, further comprising:
a second word line coupled to the second gate terminal of the second transistor and the fourth gate terminal of the fourth transistor,
wherein the second source terminal of the second transistor is coupled to the first source line, and the fourth source terminal of the fourth transistor is coupled to the second source line.

18. The memory circuit of claim 17, wherein
the first transistor is a first type;
the second transistor is a second type different from the first type;
the third transistor is the first type;
the fourth transistor is the second type;
the first transistor is on a first level;
the second transistor is on a second level different from the first level;
the third transistor is on the first level; and
the fourth transistor is on the second level.

19. The memory circuit of claim 14, further comprising:
a third source line coupled to the second source terminal of the second transistor; and
a fourth source line coupled to the fourth source terminal of the fourth transistor,
wherein the second gate terminal of the second transistor and the fourth gate terminal of the fourth transistor are coupled to each other, and are further coupled to the first word line and the first gate terminal and the third gate terminal.

20. A method of operating a memory circuit, the method comprising:
performing a write operation of a memory cell, the performing the write operation of the memory cell comprises:
storing a first logical value in the memory cell by a first transistor of a selection circuit, the selection circuit being coupled to the memory cell; or
storing a second logical value in the memory cell by a second transistor of the selection circuit, the second logical value being different from the first logical value; and
performing a read operation of the memory cell by the first transistor of the selection circuit.
